(19) United States
(12) Patent Application Publication
(10) Pub. No.: US 2025/0374776 A1
(43) Pub. Date: Dec. 4, 2025

(54) DISPLAY DEVICE

(71) Applicant: Samsung Display Co., Ltd., Yongin-Si (KR)

(72) Inventors: See Ook LEE, Yongin-si (KR); Min Ji KIM, Yongin-si (KR); Han Ho PARK, Yongin-si (KR); Chung Seok LEE, Yongin-si (KR)

(21) Appl. No.: 19/007,585

(22) Filed: Jan. 2, 2025

(30) Foreign Application Priority Data
May 28, 2024 (KR) 10-2024-0069361

(51) Int. Cl. H10K 59/131; H01L 23/498; H10K 59/95; H10K 102/00

(52) U.S. Cl. CPC H10K 59/131; H01L 23/49838; H10K 59/95; H10K 2102/311

(57) ABSTRACT

The disclosure relates to a display device capable of minimizing an attachment area of a driving circuit board near a curved or diagonal edge of a display device and an electronic device. A display device includes a display panel comprising a display area and a non-display area; a first circuit board being bendable and connected to a non-display area of the display panel; a driving circuit disposed on the first circuit board; and a second circuit board connected to the first circuit board, wherein the first circuit board comprises a first side overlapping the display panel and a second side overlapping the second circuit board with the driving circuit disposed between the first side and the second side, the first side is disposed between the display area and a pad of the display panel, and an extension direction of the first side intersects an extension direction of the second side.

### CROSS-REFERENCE TO RELATED APPLICATION

This application claims priority from Korean Patent Application No. 10-2024-0069361 filed on May 28, 2024 in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to a display device, and more particularly, to a display device and an electronic device capable of minimizing an attachment area of a driving circuit board in a curved or diagonal area.

### 2. Description of the Related Art

Since an organic light-emitting diode (OLED) display is self-emissive and does not require a separate light source unlike a liquid crystal display, its thickness and weight may be reduced. In addition, an OLED display has garnered attention as a next-generation display for TVs, monitors, and portable electronic devices due to its superior characteristics such as low power consumption, high luminance, and high response speed.

### SUMMARY

Aspects of the present disclosure provide a display device capable of minimizing an attachment area of a driving circuit board near a curved or diagonal edge of a display device.

According to one embodiment of the present disclosure, there is provided a display device comprising: a display panel comprising a display area and a non-display area; a first circuit board connected to a non-display area of the display panel, the first circuit board being bendable; a driving circuit disposed on the first circuit board; and a second circuit board connected to the first circuit board, wherein the first circuit board comprises a first side overlapping the display panel and a second side overlapping the second circuit board with the driving circuit disposed between the first side and the second side, the first side is disposed between the display area and a pad of the display panel, and an extension direction of the first side intersects an extension direction of the second side.

An angle between the extension direction of the first side and the extension direction of the second side is greater than 0 degrees and less than 90 degrees.

The angle between the extension direction of the first side and the extension direction of the second side is 3 degrees.

An entirety of the first side is on the display panel, and an entirety of the second side is on the second circuit board.

The first side is in contact with the display panel, and the second side is in contact with the second circuit board.

The first circuit board further comprises: a first groove disposed on a third side, the third side extending between a first end of the first side and a first end of the second side; and a second groove disposed on a fourth side between a second end of the first side and a second end of the second side.

The first groove and the second groove are disposed across the first circuit board each other.

An imaginary line passing through a center of the first groove and a center of the second groove intersects the extension direction of the first side.

An imaginary line passing through a center of the first groove and a center of the second groove is parallel to the extension direction of the second side.

An imaginary line passing through a center of the first groove and a center of the second groove is disposed between the first side and the driving circuit.

An imaginary line passing through a center of the first groove and a center of the second groove is disposed between the second side and the driving circuit.

An imaginary line passing through a center of the first groove and a center of the second groove is parallel to an extension direction of the driving circuit.

The extension direction of the driving circuit is parallel to the extension direction of the second side, and an imaginary line passing through the center of the first groove and the center of the second groove is parallel to the extension direction of the second side.

An imaginary line passing through a center of the first groove and a center of the second groove intersects an extension direction of the driving circuit.

The extension direction of the driving circuit is parallel to the extension direction of the first side, and an imaginary line passing through the center of the first groove and the center of the second groove is parallel to the extension direction of the second side.

The first groove of the third side is recessed toward the fourth side, and the second groove of the fourth side is recessed toward the third side.

An edge of the display panel overlapping the first circuit board comprises a first curved portion (CV1).

An edge of the display area comprises a second curved portion (CV2) disposed to correspond to the first curved portion.

The first side is disposed in the non-display area between the first curved portion and the second curved portion.

The first side is parallel to a tangent line (LL) of the first curved portion.

An imaginary straight line that perpendicularly intersects the first side and passes through a center of the first side perpendicularly intersects a tangent line of the first curved portion.

The first circuit board further comprises a plurality of panel terminals connected to the display panel, and an imaginary straight line that perpendicularly intersects the first side and passes through the center of the first side passes through a center of any one of the plurality of panel terminals.

The display device further comprises a plurality of data lines (DL) connected to the driving circuit and disposed in the display area, and the any one panel terminal is connected to any one data line positioned at a center among the plurality of data lines.

The any one panel terminal is a panel terminal positioned at a center among the plurality of panel terminals.

An edge of the display panel overlapping the first circuit board comprises a first diagonal portion.

An edge of the display area comprises a second diagonal portion extending parallel to the first diagonal portion.

The first side is disposed in the non-display area between the first diagonal portion and the second diagonal portion.

The first side is parallel to the first diagonal portion.

An imaginary straight line which perpendicularly intersects the first side and passes through a center of the first side perpendicularly intersects the first diagonal portion.

The first circuit board further comprises a panel terminal connected to the display panel, and the panel terminal extends in a direction perpendicular to the extension direction of the first side.

The first circuit board further comprises a panel terminal connected to the display panel, and the panel terminal extends in a direction perpendicular to the extension direction of the second side.

The first circuit board further comprises a plurality of panel terminals connected to the display panel, and an arrangement direction of the plurality of panel terminals is parallel to the extension direction of the first side.

The display device further comprises a plurality of pads disposed on the display panel and respectively connected to the plurality of panel terminals, and an arrangement direction of the plurality of pads is parallel to the extension direction of the first side.

The first circuit board comprises a plurality of connection lines connected to the plurality of panel terminals and the driving circuit, an extension direction of the driving circuit is parallel to the extension direction of the second side, lengths of the plurality of connection lines increases along the extension direction of the driving circuit, and a greater length correlates with a greater width for the plurality of connection lines.

The first circuit board further comprises a plurality of board terminals connected to the second circuit board, and an arrangement direction of the plurality of board terminals is parallel to the extension direction of the second side.

The first circuit board further comprises a trench disposed between the first groove and the second groove.

The trench extends between the first groove and the second groove.

The first circuit board further comprises a plurality of trenches disposed between the first groove and the second groove.

The plurality of trenches are disposed to be spaced apart from each other.

The first circuit board comprises: at least one first trench disposed in a top surface of the first circuit board; and at least one second trench disposed in a bottom surface of the first circuit board.

The at least one first trench and the at least one second trench overlap each other.

In plan view, the second trench is disposed between adjacent first trenches.

An imaginary line passing through a center of each groove of the plurality of first circuit boards is parallel to a straight portion of the display panel.

An imaginary line passing through a center of each of the plurality of second circuit boards is parallel to a straight portion of the display panel.

According to one embodiment of the present disclosure, there is provided an electronic device comprising: a display device including a processor, memory and display device, wherein the display device comprising: a display panel comprising a display area and a non-display area; a first circuit board connected to a non-display area of the display panel, the first circuit board being bendable; a driving circuit disposed on the first circuit board; and a second circuit board connected to the first circuit board, wherein the first circuit board comprises a first side overlapping the display panel and a second side overlapping the second circuit board with the driving circuit disposed between the first side and the second side, the first side is disposed between the display area and a pad of the display panel, and an extension direction of the first side intersects an extension direction of the second side.

According to the display device of one embodiment, the attachment area of the driving circuit board in the curved or diagonal area may be minimized. Accordingly, the size of the display area having a curved or diagonal shape may be prevented from being reduced.

Additionally, according to the display device of one embodiment, the driving circuit board may be easily bent.

Additionally, according to the display device of one embodiment, the stress at the bending portion of the driving circuit board may be reduced.

Additionally, according to the display device of one embodiment, the resistance deviation of the connection lines of the driving circuit board may be reduced.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view illustrating a display device according to one embodiment;

FIG. 2 is a plan view illustrating a display panel of FIG. 1;

FIG. 3 is an enlarged view of area A1 of FIG. 1;

FIG. 4 is an enlarged view of area A2 of FIG. 1;

FIG. 5 illustrates another embodiment of a first driving circuit board;

FIG. 6 illustrates still another embodiment of the first driving circuit board;

FIG. 7 illustrates still another embodiment of the first driving circuit board;

FIG. 8 illustrates still another embodiment of the first driving circuit board;

FIG. 9 is a plan view of the first driving circuit board according to still another embodiment;

FIG. 10 is a cross-sectional view taken along line I-I′ of FIG. 9;

FIG. 11 is a plan view of the first driving circuit board according to still another embodiment;

FIG. 12 is a cross-sectional view taken along line II-II′ of FIG. 11;

FIG. 13 is a plan view of the first driving circuit board according to still another embodiment;

FIG. 14 is a cross-sectional view taken along line III-III′ of FIG. 13;

FIG. 15 is a cross-sectional view of another embodiment taken along line III-III′ of FIG. 13;

FIG. 16 is a cross-sectional view of still another embodiment taken along line III-III′ of FIG. 13;

FIG. 17 is a plan view showing a display device according to another embodiment; and

FIG. 18 is an enlarged view of area A3 of FIG. 17.

FIG. 19 is a block diagram of an electronic device according to one embodiment.

FIGS. 20, 21 and 22 are schematic diagrams of electronic devices according to various embodiments.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited to any order or priority by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or in whole. As will be clearly appreciated by those skilled in the art, modifications in interactions and operations are possible. Various embodiments can be practiced individually or in combination.

Hereinafter, embodiments will be described in detail with reference to the accompanying drawings.

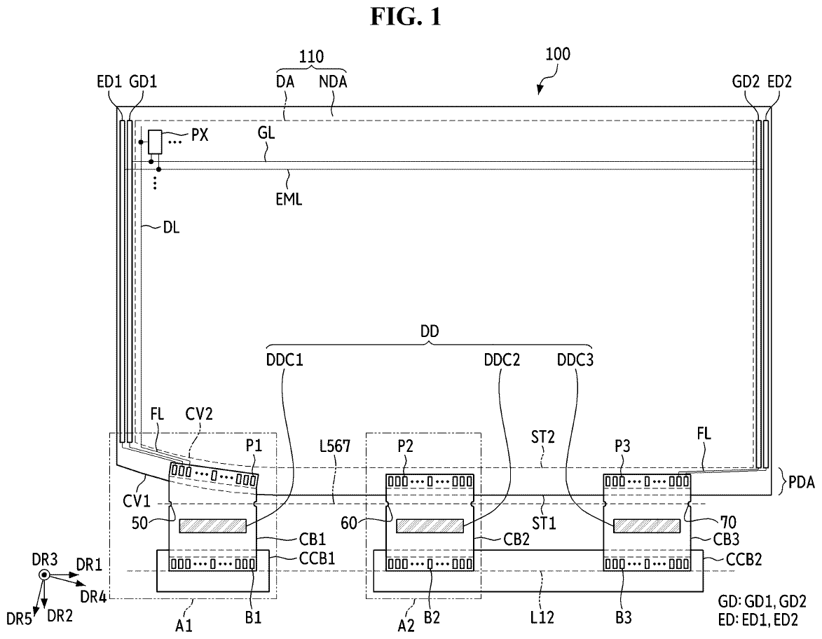

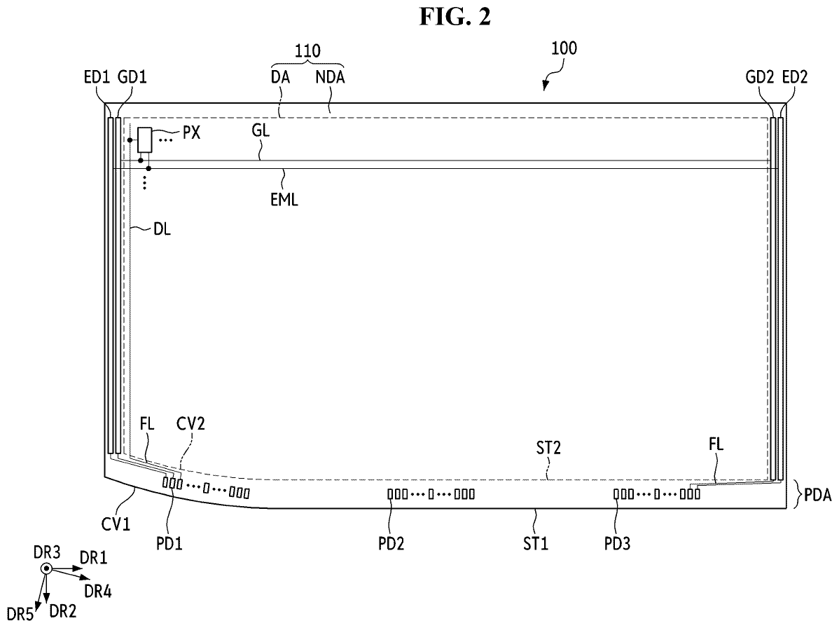

FIG. 1 is a plan view illustrating a display device 100 according to one embodiment. FIG. 2 is a plan view illustrating a display panel 110 of FIG. 1. FIG. 2 excludes a data driver that is shown in FIG. 1.

Referring to FIGS. 1 and 2, the display device 100, which is a device for displaying a moving image or a still image, may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are presented as examples, and the display device 100 may be applicable to various other types of electronic devices not explicitly mentioned herein.

The display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display including an ultra-small light emitting diode such as a micro or nano light emitting diode (micro LED or nano LED), but is not limited thereto. For example, the display device 100 may be another type of display device other than a light emitting display device. In the following, embodiments in which the display device 100 is a light emitting display device (e.g., an organic light emitting display device) will be disclosed.

The display device 100 may include the display panel 110, and a gate driver GD, an emission driver ED, and a data driver DD that supply driving signals to pixels PX of the display panel 110. Here, the pixel PX may be disposed in the display area of the display panel 110, the gate driver GD and the emission driver ED may be disposed in a non-display area NDA of the display panel 110, and the data driver DD may be connected to the non-display area NDA of the display panel 110 through first circuit boards (hereinafter referred to as driving circuit boards CB1, CB2, and CB3).

The display device 100 may further include a power supply unit and a timing controller. The power supply unit may supply power voltages to the pixels PX, the gate driver GD, the emission driver ED, and the data driver DD. The timing controller may control the operations of a first gate driver GD1 and a second gate driver GD2 of the gate driver GD, a first emission driver ED1 and a second emission driver ED2 of the emission driver ED, and the data driver DD.

The display panel 110 may have a rectangular shape in plan view. FIGS. 1 and 2 illustrate the display panel 110 in which a horizontal length (e.g., a length in a first direction DR1) is greater than a vertical length (e.g., a length in a second direction DR2), but the shape of the display panel 110 is not limited thereto. For example, the display panel 110 may have a shape with a vertical length greater than a horizontal length, a square shape, or the like. The display panel 110 may include an edge of a rounded corner. For example, as in the example illustrated in FIG. 1, one corner of the display panel 110 may have a curved portion CV1 (hereinafter referred to as a first curved portion CV1). A straight portion ST1 (hereinafter referred to as a first straight portion ST1) of the display panel 110 may be disposed on one side of the first curved portion CV1. The first straight portion ST1 may extend, for example, along the first direction DR1.

The display panel 110 may be provided as a rigid panel that does not transform into a different shape, or as a flexible panel that can be at least partially folded, bent, or rolled. The display panel 110 may be provided to the display device 100 without bending, or may be provided to the display device 100 while being partially bent.

The display panel 110 may include a display area DA and the non-display area NDA.

In the display area DA, a plurality of pixels PX may be disposed. The plurality of pixels PX may display an image. The plurality of pixels PX may be connected to gate lines GL, emission control lines EML, data lines DL, and power lines. Each of the gate line GL and the emission control line EML may extend along the first direction DR1, and the data line DL may extend along the second direction DR2. Here, the first direction DR1 is a horizontal direction, the second direction DR2 is a vertical direction, and the first direction DR1 and the second direction DR2 may intersect vertically.

The non-display area NDA may be disposed around the display area DA. In one embodiment, the non-display area NDA may surround the display area DA.

The display area DA may have various shapes depending on embodiments. For example, the display area DA may have a quadrilateral shape, a non-quadrilateral polygonal shape, a circular shape, an elliptical shape, or another shape. In one embodiment, the display area DA may have a shape that is similar to the shape of the display panel 110. For example, as in the example illustrated in FIG. 1, one corner of the display area DA may have a curved portion CV2 (hereinafter referred to as a second curved portion CV2). As a specific example, the second curved portion CV2 of the display area may be disposed to follow the outline of the first curved portion CV1 of the display panel 110. The curvature of the second curved portion CV2 and the curvature of the first curved portion CV1 may be the same. A straight portion (hereinafter referred to as a second straight portion ST2) of the display area DA may be disposed on one side of the second curved portion CV2. The second straight portion ST2 may extend, for example, along the first direction DR1. The first straight portion ST1 and the second straight portion ST2 may be disposed parallel to each other.

As illustrated in FIG. 2, the non-display area NDA may include a pad area PDA in which a plurality of pads are disposed. For example, the pad area PDA may be disposed in the non-display area NDA (e.g., lower non-display area) positioned below the display area DA. The plurality of pads PD may be disposed along the first direction DR1.

The gate driver GD and the emission driver ED may be disposed in the non-display area NDA. For example, since the gate driver GD may include the first gate driver GD1 and the second gate driver GD2, and the emission driver ED may include the first emission driver ED1 and the second emission driver ED2, the first gate driver GD1 and the first emission driver ED1 may be disposed in the non-display area NDA (e.g., the left non-display area) positioned on the left side of the display area DA, and the second gate driver GD2 and the second emission driver ED2 may be disposed in the non-display area NDA (e.g., the right non-display area) positioned on the right side of the display area DA.

The gate driver GD may drive the gate lines GL. For example, the first gate driver GD1 and the second gate driver GD2 may supply gate signals to the gate lines GL, respectively. The gate lines GL may be connected to the first gate driver GD1 and the second gate driver GD2. For example, one side of each of the gate lines GL may be electrically connected to the first gate driver GD1, and the other side of each of the gate lines GL may be electrically connected to the second gate driver GD2.

The emission driver ED may drive the emission control lines EML. For example, the first emission driver ED1 and the second emission driver ED2 may supply emission control signals to the emission control lines EML, respectively. The emission control lines EML may be connected to the first emission driver ED1 and the second emission driver ED2. As a specific example, one side of each of the emission control lines EML may be electrically connected to the first emission driver ED1, and the other side of each of the emission control lines EML may be electrically connected to the second emission driver ED2.

The driving circuit boards may include a first driving circuit board CB1, a second driving circuit board CB2, and a third driving circuit board CB3. Although three driving circuit boards CB1, CB2, and CB3 are disclosed in the present embodiment, the number of driving circuit boards is not limited to three. Each of the driving circuit boards may be referred to as a “first circuit board.”

The driving circuit boards CB1, CB2, CB3 may be connected to the display panel 110 and second circuit boards (hereinafter referred to as control circuit boards CCB1 and CCB2). For example, as illustrated in FIGS. 1 and 2, the first driving circuit board CB1 may be connected to first pads PD1 of the display panel 110 and the first control circuit board CCB1, the second driving circuit board CB2 may be connected to second pads PD2 of the display panel 110 and the second control circuit board CCB2, and the third driving circuit board CB3 may be connected to third pads PD3 of the display panel 110 and the second control circuit board CCB2. Each of the driving circuit boards CB1 and CB3 may be a flexible film such as a chip on film (COF), a printed circuit board (PCB), or a flexible printed circuit board (FPCB) that can be bent, but is not limited thereto.

The gap (e.g., gap in the first direction DR1) between adjacent driving circuit boards may be of a constant size. For example, the gap between the first driving circuit board CB1 and the second driving circuit board CB2 and the gap between the second driving circuit board CB2 and the third driving circuit board CB3 may be the same.

Each of the driving circuit boards CB1, CB2, CB3 may include a plurality of terminals (or bumps). For example, the first driving circuit board CB1 may include a plurality of first panel terminals P1 connected to a plurality of first pads PD1 of the display panel 110 and a plurality of first board terminals B1 connected to the first control circuit board CCB1 (e.g., the first terminals of the first control circuit board CCB1), the second driving circuit board CB2 may include a plurality of second panel terminals P2 connected to a plurality of second pads PD2 of the display panel 110 and a plurality of second board terminals B2 connected to the second control circuit board CCB2 (e.g., the second terminals of the second control circuit board CCB2), and the third driving circuit board CB3 may include a plurality of third panel terminals P3 connected to a plurality of third pads PD3 of the display panel 110 and a plurality of third board terminals B3 connected to the second control circuit board CCB2 (e.g., the third terminals of the second control circuit board CCB2).

The first driving circuit board CB1 may be connected to the non-display area NDA between the first curved portion CV1 and the second curved portion CV2. Each of the second driving circuit board CB2 and the third driving circuit board CB3 may be connected to the non-display area NDA between the first straight portion ST1 and the second straight portion ST2.

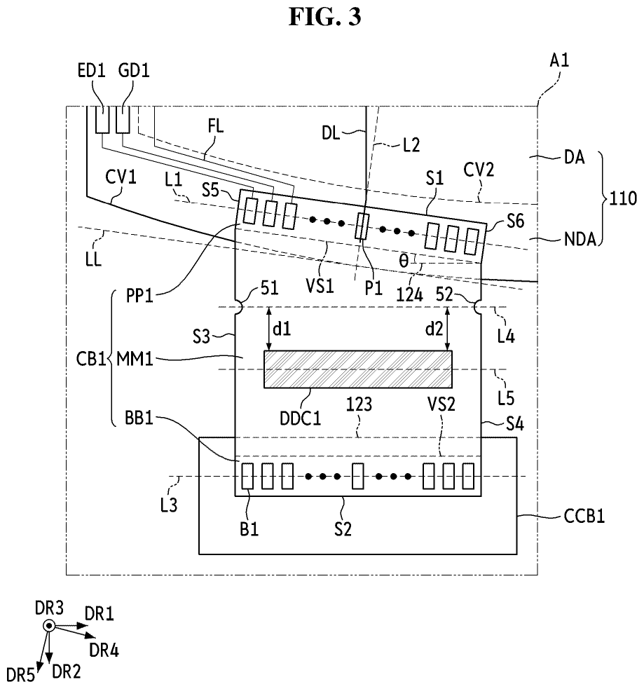

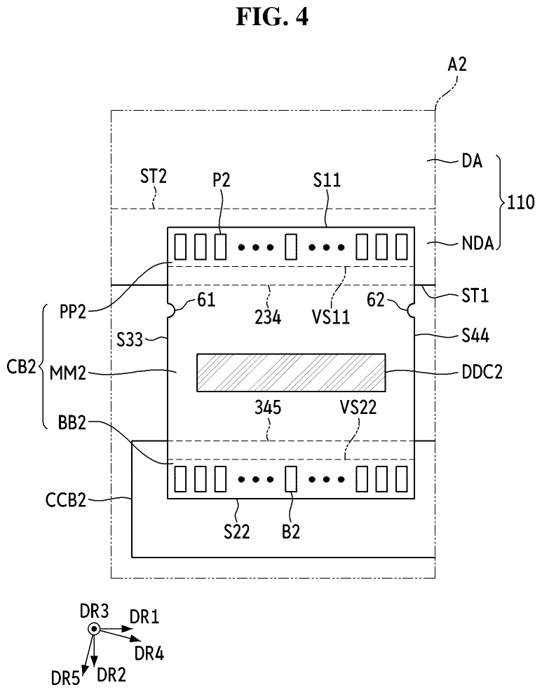

Grooves 50, 60, and 70 of the driving circuit boards CB1 to CB3 may be disposed along one direction. For example, the grooves 50 of the first driving circuit board CB1, the grooves 60 of the second driving circuit board CB2, and the grooves 70 of the third driving circuit board CB3 may line up in the first direction DR1. As a specific embodiment, an imaginary line L567 that passes through the centers of the grooves 50 of the first driving circuit board CB1, centers of the grooves 60 of the second driving circuit board CB2, and centers of the grooves 70 of the third driving circuit board CB3 may be parallel to the first straight portion ST1 of the display panel 110. Accordingly, although the arrangement directions of the pads (e.g., PD1 and PD2, or PD1 and PD3) of the driving circuit boards CB1 to CB3 are different, or the edge of the display panel 110 has a shape including the curved portion CV1 and the straight portion ST1, when bending the circuit board, the driving circuit boards CB1 and CB3 may be easily bent to the rear surface of the display panel 110 together. The grooves 50 of the first driving circuit board CB1 may include a first groove 51 and a second groove 52 of FIG. 3, which will be described later, and the grooves 60 of the second driving circuit board CB2 may include a first groove 61 and a second groove 62 of FIG. 4, which will be described later. Likewise, the grooves 70 of the third driving circuit board CB3 may include a first groove and a second groove. An “arrangement direction,” as used herein, refers to a direction defined by centers of a plurality of elements being connected.

A timing controller and a power supply circuit may be disposed on at least one of the first control circuit board CCB1 or the second control circuit board CCB2. The first control circuit board CCB1 and the second control circuit board CCB2 may be electrically connected to each other through a connector. Each of the first control circuit board CCB1 and the second control circuit board CCB2 may be a flexible film such as a chip on film (COF), a printed circuit board (PCB), or a flexible printed circuit board (FPCB), but is not limited thereto. For example, the first control circuit board CCB1 and the second control circuit board CCB2 may be printed circuit boards made of a rigid material. In the present embodiment, two control circuit boards CCB1 and CCB2 are disclosed, but the number of control circuit boards is not limited thereto.

The first control circuit board CCB1 and the second control circuit board CCB2 may be disposed along one direction. For example, the first control circuit board CCB1 and the second control circuit board CCB2 may be disposed along the first direction DR1 as depicted in FIG. 1. An imaginary line L12 passing through the center of the first control circuit board CCB1 and the center of the second control circuit board CCB2 may be parallel to the first straight portion ST1 of the display panel 110. Accordingly, although the arrangement directions of the pads (e.g., PD1 and PD2, or PD1 and PD3) of the driving circuit boards CB1 to CB3 are different, or the edge of the display panel 110 has the curved portion CV1 and the straight portion ST1, the control circuit boards CCB1 and CCB2 may be easily bent to the rear surface of the display panel 110 together when bending the circuit board.

The data driver DD may include a plurality of driving circuits DDC1, DDC2, and DDC3 (hereinafter referred to as data driving circuits) arranged along the first direction DR1. For example, the data driver DD may include a first data driving circuit DDC1 mounted on the first driving circuit board CB1, a second data driving circuit DDC2 mounted on the second driving circuit board CB2, and a third data driving circuit DDC3 mounted on the third driving circuit board CB3. Each of the data driving circuits DDC1 to DDC3 may include, for example, an integrated circuit.

Each of the data driving circuits DDC1 to DDC3 may be electrically connected to each of the pads PD1 to PD3 of the display panel 110 through each of the driving circuit boards CB1 and CB3. For example, the first data driving circuit DDC1 may be electrically connected to the first pads PD1 of the display panel 110 through the first panel terminals P1 of the first driving circuit board CB1, the second data driving circuit DDC2 may be electrically connected to the second pads PD2 of the display panel 110 through the second panel terminals P2 of the second driving circuit board CB2, and the third data driving circuit DDC3 may be electrically connected to the third pads PD3 of the display panel 110 through the third panel terminals P3 of the third driving circuit board CB3.

A plurality of data lines DL may be connected to the data driver DD. For example, the plurality of data lines DL may be divided and connected to a plurality of data driving circuits DDC1 to DDC3. As a specific example, the plurality of data lines DL may include a plurality of first data lines connected to the first data driving circuit DDC1, a plurality of second data lines connected to the second data driving circuit DDC2, and a plurality of third data lines connected to the third data driving circuit DDC3.

The first panel terminals P1 of the first driving circuit board CB1 may include a plurality of first control terminals, a plurality of first power terminals, and a plurality of first data terminals. The first control terminals may be connected to a timing controller disposed on the second control circuit board CCB2. For example, since the second control circuit board CCB2 and the first control circuit board CCB1 may be electrically connected to each other, the first control terminals may be connected to the timing controller of the second control circuit board CCB2 through the first control circuit board CCB1. The first power terminals may be connected to a power supply unit disposed on the second control circuit board CCB2. For example, since the second control circuit board CCB2 and the first control circuit board CCB1 may be electrically connected to each other, the first power terminals may be connected to the power supply unit of the second control circuit board CCB2 through the first control circuit board CCB1. The first data terminals may be connected to the first data driving circuit DDC1. The first board terminals B1 of the first driving circuit board CB1 may include first control terminals, first power terminals, and first data terminals corresponding to the first panel terminals P1. The first control terminals of the first board terminals B1 may be connected to the first control terminals of the first panel terminals P1, the first power terminals of the first board terminals B1 may be connected to the first power terminals of the first panel terminals P1, and the first data terminals of the first board terminals B1 may be connected to the first data driving circuit DDC1.

The second panel terminals P2 of the second driving circuit board CB2 may include a plurality of second power terminals and a plurality of second data terminals. The second power terminals may be connected to a power supply unit disposed on the second control circuit board CCB2. The second data terminals may be connected to the second data driving circuit DDC2. The second board terminals B2 of the second driving circuit board CB2 may include second power terminals and second data terminals corresponding to the second panel terminals P2. The second power terminals of the second board terminals B2 may be connected to the second power terminals of the second panel terminals P2, and the second data terminals of the second board terminals B2 may be connected to the second data driving circuit DDC2.

The third panel terminals P3 of the third driving circuit board CB3 may include a plurality of second control terminals, a plurality of third power terminals, and a plurality of third data terminals. The second control terminals may be connected to a timing controller disposed on the second control circuit board CCB2. The third power terminals may be connected to a power supply unit disposed on the second control circuit board CCB2. The third data terminals may be connected to the third data driving circuit DDC3. The third board terminals B3 of the third driving circuit board CB3 may include second control terminals, third power terminals, and third data terminals corresponding to the third panel terminals P3. The second control terminals of the third board terminals B3 may be connected to the second control terminals of the third panel terminals P3, the third power terminals of the third board terminals B3 may be connected to the third power terminals of the third panel terminals P3, and the third data terminals of the third board terminals B3 may be connected to the third data driving circuit DDC3.

The first panel terminals P1 of the first driving circuit board CB1 and the first pads PD1 of the display panel 110 may be electrically connected directly or through a connection member such as a conductive ball, the second panel terminals P2 of the second driving circuit board CB2 and the second pads PD2 of the display panel 110 may be electrically connected directly or through a connection member such as a conductive ball, and the third panel terminals P3 of the third driving circuit board CB3 and the third pads PD3 of the display panel 110 may be electrically connected directly or through a connection member such as a conductive ball.

The first board terminals B1 of the first driving circuit board CB1 and the first terminals of the first control circuit board CCB1 may be electrically connected directly or through a connection member such as a conductive ball, the second board terminals B2 of the second driving circuit board CB2 and the second terminals of the second control circuit board CCB2 may be electrically connected directly or through a connection member such as a conductive ball, and the third board terminals B3 of the third driving circuit board CB3 and the third terminals of the second control circuit board CCB2 may be electrically connected directly or through a connection member such as a conductive ball.

The first pads PD1 of the display panel 110 may include a plurality of first control pads, a plurality of first power pads, and a plurality of first data pads. The first control pads may be connected to the first control terminals of the first panel terminals P1, respectively. Additionally, the first control pads may be connected to the first gate driver GD1 and the first emission driver ED1. The first power pads may be connected to the first power terminals of the first panel terminals P1, respectively. Additionally, the first power pads may be connected to the first gate driver GD1, the first emission driver ED1, and the pixels PX. The first data pads may be connected to the first data terminals of the first panel terminals P1, respectively. Additionally, the first data pads may be connected to first data lines, respectively.

The second pads PD2 of the display panel 110 may include a plurality of second power pads and a plurality of second data pads. The second power pads may be connected to the second power terminals of the second panel terminals P2, respectively. Additionally, the second power pads may be connected to the pixels PX. The second data pads may be connected to the second data terminals of the second panel terminals P2, respectively. Additionally, the second data pads may be connected to the second data lines, respectively.

The third pads PD3 of the display panel 110 may include a plurality of second control pads, a plurality of third power pads, and a plurality of third data pads. The second control pads may be connected to the second control terminals of the third panel terminals P3, respectively. Additionally, the second control pads may be connected to the second gate driver GD2 and the second emission driver ED2. The third power pads may be connected to the third power terminals of the third panel terminals P3, respectively. Additionally, the third power pads may be connected to the pixels PX. The third data pads may be connected to the third data terminals of the third panel terminals P3, respectively. Additionally, the third data pads may be connected to the third data lines, respectively.

The first control pads and the first gate driver GD1 described above may be electrically connected to each other through corresponding fan-out lines FL, and the other first control pads and the first emission driver ED1 may be electrically connected to each other through the corresponding fan-out lines FL.

The second control pads and the second gate driver GD2 described above may be electrically connected to each other through the corresponding fan-out lines FL, and other second control pads and the second emission driver ED2 may be electrically connected to each other through the corresponding fan-out lines FL.

The first to third data pads described above may be electrically connected to the first to third data lines through the corresponding fan-out lines FL.

A gate timing control signal, an emission timing control signal, a gate clock signal, an emission clock signal, a gate start signal, an emission start signal, a high potential voltage, and a low potential voltage from the timing controller may be supplied to the first gate driver GD1 and the first emission driver ED1 through the first control terminals of the first driving circuit board CB1 and the first control pads of the display panel 110. For example, the gate timing control signal, the gate clock signal, the gate start signal, the high potential voltage, and the low potential voltage may be supplied to the first gate driver GD1, and the emission timing control signal, the emission clock signal, the emission start signal, the high potential voltage, and the low potential voltage may be supplied to the first emission driver ED1. The power signals from the power supply unit may be supplied to the first gate driver GD1, the first emission driver ED1, and the pixels PX through the first power terminals of the first driving circuit board CB1 and the first power pads of the display panel 110. The power signals may include, for example, a driving voltage, a common voltage, an initialization voltage, and a bias voltage. The data signals from the first data driving circuit DDC1 may be supplied to the first data lines through the first data terminals of the first driving circuit board CB1 and the first data pads of the display panel 110, respectively.

The power signals from the power supply unit may be supplied to the pixels PX through the second power terminals of the second driving circuit board CB2 and the second power pads of the display panel 110. The data signals from the second data driving circuit DDC2 may be supplied to the second data lines through the second data terminals of the second driving circuit board CB2 and the second data pads of the display panel 110, respectively.

The gate timing control signal, the emission timing control signal, the gate clock signal, the emission clock signal, the high potential voltage, and the low potential voltage from the timing controller may be supplied to the second gate driver GD2 and the second emission driver ED2 through the second control terminals of the third driving circuit board CB3 and the second control pads of the display panel 110. For example, the gate timing control signal, the gate clock signal, the high potential voltage, and the low potential voltage may be supplied to the second gate driver GD2, and the emission timing control signal, the emission clock signal, the high potential voltage, and the low potential voltage may be supplied to the second emission driver ED2. The power signals from the power supply unit may be supplied to the second gate driver GD2, the second emission driver ED2, and the pixels PX through the third power terminals of the third driving circuit board CB3 and the third power pads of the display panel 110. The data signals from the third data driving circuit DDC3 may be supplied to the third data lines through the third data terminals of the third driving circuit board CB3 and the third data pads of the display panel 110, respectively. The high potential voltage described above may be higher than the driving voltage, and the low potential voltage may be lower than the common voltage.

FIG. 3 is an enlarged view of area A1 of FIG. 1.

As illustrated in FIG. 3, the first driving circuit board CB1 may have a polygonal shape including a first side S1, a second side S2, a third side S3, a fourth side S4, a fifth side S5, and a sixth side S6. However, the shape of the first driving circuit board CB1 is not limited to what is depicted in the figures, and may have various shapes different from the shape illustrated in FIG. 3. Each side S1, S2, S3, S4, S5, S6 has a first end and a second end.

The first side S1 of the first driving circuit board CB1 may extend along a fourth direction DR4. Here, the fourth direction DR4 may be a direction extending within an angle (e.g., 90 degrees) formed by the first direction DR1 and the second direction DR2, and the angle (e.g., 90 degrees) between the first direction DR1 and the fourth direction DR4 may be smaller than the angle between the first direction DR1 and the second direction DR2. The first side S1 may be disposed on the display panel 110. The first side S1 may overlap the display panel 110. For example, the first side S1 may overlap the non-display area NDA of the display panel 110 in the third direction DR3. As a specific example, the entirety of the first side S1 may be on the non-display area NDA of the display panel 110. According to one embodiment, the first side S1 may be disposed between the display area DA of the display panel 110 and the pads (e.g., the first pads PD1) of the display panel 110.

The fifth side S5 of the first driving circuit board CB1 may extend along a fifth direction DR5 from the first end of the first side S1. The fifth direction DR5 may extend within an angle (e.g., a 90-degree angle) formed by the reverse first direction (that is in opposite direction of the first direction DR1) and the second direction DR2. The angle between the reverse first direction and the fifth direction DR5 may be smaller than the angle between the reverse first direction and the second direction DR2. The fifth side S5 may be disposed on the display panel 110. The fifth side S5 may overlap the display panel 110. For example, the fifth side S5 may overlap the non-display area NDA of the display panel 110 in the third direction DR3. In an embodiment, the entire length of the fifth side S5 may be on the non-display area NDA of the display panel 110.

The sixth side S6 of the first driving circuit board CB1 may extend along the fifth direction DR5 from the second end of the first side S1. The sixth side S6 may be disposed to face the fifth side S5. For example, the sixth side S6 and the fifth side S5 may both be perpendicular to the fourth direction DR4. The length of the sixth side S6 and the length of the fifth side S5 may be the same. The length of the sixth side S6 may be less than the length of the first side S1. The sixth side S6 and the fifth side S5 may be parallel. The sixth side S6 may be disposed on the display panel 110. The sixth side S6 may overlap the display panel 110. For example, the sixth side S6 may overlap the non-display area NDA of the display panel 110 in the third direction DR3. In an embodiment, the entire length of the sixth side S6 may be on the non-display area NDA of the display panel 110.

The third side S3 of the first driving circuit board CB1 may extend from the second end of the fifth side S5. For example, since the first end of the fifth side S5 is connected to the first end of the first side S1, the third side S3 may extend from the second end of the fifth side S5 in the second direction DR2. The length of the third side S3 may be greater than the length of the first side S1. The first end of the third side S3 may be disposed on the display panel 110. the first end of the third side S3 may overlap the display panel 110. The second end of the third side S3 may be disposed on the first control circuit board CCB1. The second end of the third side S3 may overlap the first control circuit board CCB1. In other words, a portion of the third side S3 may overlap the display panel 110, and another portion of the third side S3 may overlap the first control circuit board CCB1. The first groove 51 may be disposed on the third side S3. For example, the first groove 51 may be disposed in a portion of the third side S3 that does not overlap the display panel 110 or the first control circuit board CCB1. The first groove 51 of the third side S3 may be a cutout that is recessed toward the fourth side S4. For example, the first groove 51 may have the shape of any one of a semicircle or a parabola with the vertex closest to the fourth side S4. The first driving circuit board CB1 may be easily bent (or folded) at the first groove 51 and the second groove 52. Since the first driving circuit board CB1 attached to the display panel 110 and the first control circuit board CCB1 may be bent toward the back of the display panel 110, the first driving circuit board CB1 may be easily bent at the first groove 51 and the second groove 52.

The fourth side S4 of the first driving circuit board CB1 may extend from the second end of the sixth side S6. Since the first end of the sixth side S6 is connected to the second end of the first side S1, the fourth side S4 may extend from the second end of the sixth side S6 in the second direction DR2. In the shape of the first driving circuit board CB1, the fourth side S4 may form the opposite side to the third side S3. The third side S3 and the fourth side S4 may be parallel to each other. The length of the fourth side S4 may be greater than the length of the first side S1 and may be less than the length of the third side S3. the first end of the fourth side S4 may be disposed on the display panel 110. The first end of the fourth side S4 may overlap the display panel 110. The second end of the fourth side S4 may be disposed on the first control circuit board CCB1. The second end of the fourth side S4 may overlap the first control circuit board CCB1. In other words, a portion of the fourth side S4 may overlap the display panel 110, and another portion of the fourth side S4 may overlap the first control circuit board CCB1. The second groove 52 may be disposed on the fourth side S4. For example, the second groove 52 may be disposed at a portion of the fourth side S4 that does not overlap the display panel 110 or the first control circuit board CCB1. The second groove 52 of the fourth side S4 may be a cutout that is recessed toward the third side S3. For example, the second groove 52 may have the shape of any one of a semicircle or a parabola with its vertex closest to the third side S3. The second groove 52 and the first groove 51 may be disposed to face each other. For example, the second groove 52 and the first groove 51 may face each other in the first direction DR1. The second groove 52 and the first groove 51 may have shapes that are symmetrical to each other. For example, the second groove 52 and the first groove 51 may have shapes that are symmetrical to each other with respect to an imaginary extension line extending along the second direction DR2 and including the midpoint between the first groove 51 and the second groove 52.

The second side S2 of the first driving circuit board CB1 may extend between the second end of the third side S3 and the second end of the fourth side S4. Since the first end of the third side S3 is connected to the second end of the fifth side S5, and first end of the fourth side S4 is connected to the second end of the sixth side S6, the first end of the sixth side S6 may be connected to the other end of the fourth side S4, and the other end of the second side S2 may be connected to the second end of the third side S3. In other words, the second side S2 may extend from the second end of the third side S3 to the second end of the fourth side S4 along the first direction DR1. The length of the second side S2 may be less than the length of the first side S1.

As illustrated in FIG. 3, the first driving circuit board CB1 may include a mounting portion MM1, a panel connection portion PP1, and a board connection portion BB1.

The panel connection portion PP1 may be disposed on the display panel 110. For example, the panel connection portion PP1 may be disposed in the non-display area NDA (e.g., the non-display area NDA of a curved shape between the first curved portion CV1 and the second curved portion CV2) of the display panel 110 to overlap the first pads PD1 of the display panel 110. The panel connection portion PP1 may include the plurality of first panel terminals P1. The plurality of first panel terminals P1 of the panel connection portion PP1 may overlap the plurality of first pads PD1 of the display panel 110, respectively. The first panel terminals P1 may be disposed along the fourth direction DR4. The panel connection portion PP1 may be a portion connected to the display panel 110. For example, since the first panel terminals P1 of the panel connection portion PP1 may be connected to the first pads PD1 of the display panel 110 by pressure and heat, the pressure and heat described above may be applied to the panel connection portion PP1. The panel connection portion PP1 may be defined by the first side S1, the second side S2, the third side S3, and a first imaginary side VS1 of the first driving circuit board CB1 described above. For example, the panel connection portion PP1 may mean an area of the first driving circuit board CB1 surrounded by the first side S1, the second side S2, the third side S3, and the first imaginary side VS1. Here, the first imaginary side VS1 may mean an imaginary side connecting the second end (e.g., the intersection point between the first side S1 and the fifth side S5) of the fifth side S5 and the second end (e.g., the intersection point between the first side S1 and the sixth side S6) of the sixth side S6. The first imaginary side VS1 may be parallel to the first side S1.

The board connection portion BB1 may be disposed on the first control circuit board CCB1. For example, the board connection portion BB1 may be disposed on the first terminal area of the first control circuit board CCB1 to overlap the first terminals of the first control circuit board CCB1. The board connection portion BB1 may include the plurality of first board terminals B1. The plurality of first board terminals B1 of the board connection portion BB1 may overlap a plurality of first terminals of the first control circuit board CCB1, respectively. The first board terminals B1 may be disposed along the first direction DR1. The board connection portion BB1 may be a portion connected to the first control circuit board CCB1. For example, since the first board terminals B1 of the board connection portion BB1 may be respectively connected to the first terminals of the first control circuit board CCB1 by pressure and heat, the pressure and heat described above may be applied to the board connection portion BB1. The board connection portion BB1 may be defined by the third side S3, the fourth side S4, the second side S2, and a second imaginary side VS2 of the first driving circuit board CB1 described above. For example, the board connection portion BB1 may mean an area of the first driving circuit board CB1 surrounded by the third side S3, the fourth side S4, the second side S2, and the second imaginary side VS2. Here, the second imaginary side VS2 may mean an imaginary side connecting the third S3 and the fourth side S4 between an overlapping side 123 of the first control circuit board CCB1 and the first board terminal B1. The second imaginary side VS2 may be parallel to the second side S2. Here, the overlapping side 123 of the first control circuit board CCB1 may mean a side of the first control circuit board CCB1 overlapping the first driving circuit board CB1 (e.g., the mounting portion MM1 of the first driving circuit board CB1).

The mounting portion MM1 may be disposed between the panel connection portion PP1 and the board connection portion BB1. The mounting portion MM1 may include the first data driving circuit DDC1. For example, the first data driving circuit DDC1 may be disposed (or mounted) on the mounting portion MM1. The first groove 51 and second groove 52 described above may be disposed between the first data driving circuit DDC1 and the panel connection portion PP1. The mounting portion MM1 may be defined by the third side S3, the fourth side S4, the first imaginary side VS1, and the second imaginary side VS2 of the first driving circuit board CB1. For example, the mounting portion MM1 may refer to an area of the first driving circuit board CB1 surrounded by the third side S3, the fourth side S4, the first imaginary side VS1, and the second imaginary side VS2.

For example, the longest side (e.g., the first side S1) among the sides overlapping the display panel 110 and the longest side (e.g., the second side S2) among the sides overlapping the first control circuit board CCB1 extend in a non-parallel manner. In other words, as the first side S1 is a side that overlaps the display panel 110 on one side of the first data driving circuit DDC1, and the second side S2 is a side that overlaps the first control circuit board CCB1 on the other side of the first data driving circuit DDC1, the first side S1 and the second side S2 extend in nonparallel directions. Here, the first side S1 may be in contact with the display panel 110, and the second side S2 may be in contact with the first control circuit board CCB1. The angle between the first side S1 and the second side S2 may be greater than 0 degrees. For example, the angle θ between the first imaginary side VS1 parallel to the first side S1 and an imaginary line 124 parallel to the second side S2 may be greater than 0 degrees and less than 90. For example, the angle (e.g., θ) between the extension direction of the first side S1 and the extension direction of the second side S2 may be 3 degrees. An “extension direction,” as used herein, refers to the direction in which the longest portion of an element extends.

According to one embodiment, the first side S1 of the first driving circuit board CB1 may be parallel to a tangent line LL of the first curved portion CV1. The tangent line LL may be tangent to the first curved portion CV1 at a point where an imaginary second line L2 intersects the first curved portion CV1. The imaginary second line L2 extends parallel to the fifth side S5 through a center of the panel connection portion PP1. Additionally, an imaginary first line L1 that passes through the center of the panel connection portion PP1 to intersect the fifth side S5 perpendicularly may be parallel to the tangent line LL.

According to one embodiment, the imaginary second line L2 that passes through the center of the panel connection portion PP1 and extends in the fifth direction DR5 to intersect the first side S1 perpendicularly may also be perpendicular to the tangent line LL. In an embodiment, the imaginary second line L2 may pass through the center of any one of the first panel terminals P1 connected to the first data lines. For example, when the first data line positioned at the center among the plurality of first data lines connected to the first driving circuit board CB1 is defined as a center data line, and the first panel terminal P1 connected to the center data line is defined as a center panel terminal, the imaginary second line L2 described above may pass through the center of the central panel terminal.

According to one embodiment, the first panel terminal P1 may in along a direction parallel to the fifth side S5. For example, each of the first panel terminals P1 may extend along the fifth direction DR5.

According to one embodiment, the first board terminals B1 may be disposed along the first direction DR1. The first board terminal B1 may extend in a direction parallel to the third side S3. For example, the first board terminals B1 may extend along the second direction DR2.

According to one embodiment, an imaginary third line L3 that passes through the center of the board connection portion BB1 to intersect the fifth side S5 perpendicularly may not be parallel to the first line L1 (or the tangent line LL) described above. For example, the third line L3 and the first line L1 (or the tangent line LL) may intersect. The angle between the third line L3 and the first line L1 may be equal to the angle (e.g., 0) between the first side S1 and the second side S2 described above.

According to one embodiment, an imaginary fourth line L4 that passes through the center of the first groove 51 and the center of the second groove 52 may be parallel to the second side S2 of the first driving circuit board CB1.

According to one embodiment, the imaginary fourth line L4 described above may be positioned at the same distance from the first end and the second end of the first data driving circuit DDC1. For example, a distance d1 between the fourth line L4 and one end of the first data driving circuit DDC1 may be the same as a distance d2 between the fourth line LA and the other end of the first data driving circuit DDC1. In other words, an imaginary fifth line L5 that perpendicularly intersects the fourth side S4 and passes through the center of the first data driving circuit DDC1 may be parallel to the fourth line L4. The distance between the first data driving circuit DDC1 and the imaginary fourth line L4 may be constant. The fifth line L5 may be in the extension direction of the first data driving circuit DDC1. The extension direction of the first data driving circuit DDC1 may be parallel to the fourth line L4 (or the sixth side S6) described above and may intersect the first line L1 (or the tangent line LL).

According to one embodiment, as illustrated in FIG. 2, the first pads PD1 of the display panel 110 may be disposed along the fourth direction DR4.

Each of the first pads PD1 may extend in a direction parallel to the second side S2 of the first driving circuit board CB1. For example, each of the first pads PD1 may extend along the fifth direction DR5. In other words, the first pads PD1 may extend in the same direction as the first panel terminals P1 of the first driving circuit board CB1 described above.

According to one embodiment, since the panel connection portion PP1 of the first driving circuit board CB1 extends along the extension direction of the tangent line LL of the first curved portion CV1 (or the second curved portion CV2), the panel connection portion PP1 may be disposed along the tangent line LL in the non-display area NDA of a curved shape between the first curved portion CV1 and the second curved portion CV2. Additionally, accordingly, the panel connection portion PP1 may be disposed in the center of the non-display area NDA of a curved shape without extending into the display area DA. Accordingly, when the first driving circuit board CB1 is attached to the display panel 110 in the curved area between the first curved portion CV1 and the second curved portion CV2, the attachment area of the first driving circuit board CB1 and the display panel 110 may be minimized, and thus the size of the display area DA in the curved area may be prevented from being reduced.

FIG. 4 is an enlarged view of area A2 of FIG. 1.

As illustrated in FIG. 4, the second driving circuit board CB2 may have a polygonal shape including a first side S11, a second side S22, a third side S33, and a fourth side S44. Each of the first side S11, the second side S22, the third side S33, and the fourth side S44 has a first end and a second end. The second driving circuit board CB2 may have a different shape from the first driving circuit board CB1. However, the shape of the second driving circuit board CB2 is not limited to what is explicitly depicted in the figures, and may have various shapes different from the shape illustrated in FIG. 4 as long as the shape is different from the first driving circuit board CB1.

The first side S11 of the second driving circuit board CB2 may extend along the first direction DR1, from a first end to a second end. The first side S11 may be disposed on the display panel 110. At this time, the first side S11 may overlap the display panel 110. For example, the first side S11 may overlap the non-display area NDA of the display panel 110 in the third direction DR3. As a specific example, the entire length of the first side S11 may overlap the non-display area NDA of the display panel 110.

The second side S22 of the second driving circuit board CB2 may extend along the second direction DR2 from a first end of the first side S11. The length of the third side S33 may be greater than the length of the first side S11. A first end of the third side S33 may be disposed on the display panel 110 and overlap the display panel 110. A second end of the third side S33 may be disposed on the second control circuit board CCB2. The second end of the third side S33 may overlap the second control circuit board CCB2. In other words, a portion of the third side S33 may overlap the display panel 110 in the third direction DR3, and another portion of the third side S33 may overlap the second control circuit board CCB2 in the third direction DR3. The first groove 61 may be formed on the third side S33. For example, the first groove 61 may be disposed on a portion of the second side S22 that does not overlap the display panel 110 or the second control circuit board CCB2 described above. The first groove 61 of the third side S33 may be a cutout that is recessed toward the fourth side S44. For example, the first groove 61 may have the shape of any one of a semicircle or a parabola with its vertex closest to the fourth side S44.

The fourth side S44 of the second driving circuit board CB2 may extend from the second nd of the first side S11. The fourth side S44 has a first end and a second end, and may be disposed to form an opposite side to the third side S33. For example, the fourth side S44 and the third side S33 may face each other in the first direction DR1. The third side S33 and the fourth side S44 may be parallel to each other. The length of the fourth side S44 may be greater than the length of the first side S11 and may be the same as the length of the third side S33. The first end of the fourth side S44 may be disposed on the display panel 110 and overlap the display panel 110. The second end of the fourth side S44 may be disposed on the second control circuit board CCB2. The second end of the fourth side S44 may overlap the second control circuit board CCB2. In other words, a portion of the fourth side S44 may overlap the display panel 110, and another portion of the fourth side S44 may overlap the second control circuit board CCB2. The second groove 62 may be disposed in a portion of the fourth side S44. For example, the second groove 62 may be disposed in a portion of the fourth side S44 that does not overlap the display panel 110 and the second control circuit board CCB2 described above. The second groove 62 of the fourth side S44 may have a recessed shape toward the third side S33. For example, the second groove 62 may have the shape of any one of a semicircle or a parabola with its vertex closest to the third side S33. The second groove 62 and the first groove 61 may be disposed to face each other. For example, the second groove 62 and the first groove 61 may face each other in the first direction DR1. The second groove 62 and the first groove 61 may have shapes that are symmetrical to each other. For example, the second groove 62 and the first groove 61 may have shapes that are symmetrical to each other with respect to an imaginary extension line extending along the second direction DR2 from a midpoint between them.

The fourth side S44 of the second driving circuit board CB2 may have a first end and a second end, and extend between the second end of the third side S33 and the second end of the fourth side S44. For example, since the first end of the third side S33 is connected to the first end of the first side S11, and the first end of the fourth side S44 is connected to the second end of the first side S11, the first end of the second side S22 may be connected to the second end of the third side S33, and the second end of the second side S22 may be connected to the second end of the fourth side S44. In other words, the second side S22 may extend from the second end of the third side S33 to the second end of the fourth side S44 along the first direction DR1. The second side S22 may be disposed to form an opposing side to the first side S11. For example, the second side S22 and the first side S11 may face each other in the second direction DR2. The second side S22 and the first side S11 may be parallel to each other. The length of the second side S22 may be the same as the length of the first side S11.

As illustrated in FIG. 4, the second driving circuit board CB2 may include a mounting portion MM2, a panel connection portion PP2, and a board connection portion BB2.

The panel connection portion PP2 may be disposed on the display panel 110. For example, the panel connection portion PP2 may be disposed in the non-display area NDA (e.g., the non-display area NDA of a quadrilateral shape between the first straight portion ST1 and the second straight portion ST2) of the display panel 110 to overlap the second pads PD2 of the display panel 110. The panel connection portion PP2 may include the plurality of second panel terminals P2. The plurality of second panel terminals P2 of the panel connection portion PP2 may overlap the plurality of second pads PD2 of the display panel 110. The second panel terminals P2 may be disposed along the first direction DR1. The panel connection portion PP2 may be a portion connected to the display panel 110. For example, since the second panel terminals P2 of the panel connection portion PP2 may be connected to the second pads PD2 of the display panel 110 by pressure and heat, the pressure and heat described above may be applied to the panel connection portion PP2. The panel connection portion PP2 may be defined by the first side S11, the third side S33, the fourth side S44, and a first imaginary side VS11 of the second driving circuit board CB2 described above. For example, the panel connection portion PP2 may refer to an area of the second driving circuit board CB2 that is defined by the first side S11, the third side S33, the fourth side S44, and the first imaginary side VS11. The first imaginary side VS11 may be an imaginary side connecting the third side S33 and the fourth side S44 between an overlapping edge 234 of the display panel 110 and the second panel terminal P2. The first imaginary side VS11 may be parallel to the first side S11. Here, the overlapping edge 234 of the display panel 110 may refer to the edge of the display panel 110 that is covered by the second driving circuit board CB2 (e.g., the mounting portion MM2 of the second driving circuit board CB2).

The board connection portion BB2 may be disposed on the second control circuit board CCB2. For example, the board connection portion BB2 may be disposed on the second terminal area of the second control circuit board CCB2 to overlap the second terminals of the second control circuit board CCB2. The board connection portion BB2 may include the plurality of second board terminals B2. The plurality of second board terminals B2 of the board connection portion BB2 may overlap a plurality of second terminals of the second control circuit board CCB2, respectively. The second board terminals B2 may be disposed along the first direction DR1. The board connection portion BB2 may be a portion connected to the second control circuit board CCB2. For example, since the second board terminals B2 of the board connection portion BB2 may be connected to the second terminals of the second control circuit board CCB2 by pressure and heat, the pressure and heat described above may be applied to the board connection portion BB2. The board connection portion BB2 may be defined by the second side S22, the third side S33, the fourth side S44, and a second imaginary side VS22 of the second driving circuit board CB2 described above. For example, the board connection portion BB2 may refer to an area of the second driving circuit board CB2 that is surrounded by the second side S22, the third side S33, the fourth side S44, and the second imaginary side VS22. Here, the second imaginary side VS22 may be an imaginary line connecting the third side S33 and the fourth side S44 between an overlapping edge 345 of the second control circuit board CCB2 and the second board terminal B2. The second imaginary side VS22 may be parallel to the second side S22. Here, the overlapping edge 345 of the second control circuit board CCB2 may be an edge of the second control circuit board CCB2 that is covered by the second driving circuit board CB2 (e.g., the mounting portion MM2 of the second driving circuit board CB2).

The mounting portion MM2 may be disposed between the panel connection portion PP2 and the board connection portion BB2. The mounting portion MM2 may include the second data driving circuit DDC2. For example, the second data driving circuit DDC2 may be disposed (or mounted) on the mounting portion MM2. The first groove 61 and second groove 62 described above may be disposed between the second data driving circuit DDC2 and the panel connection portion PP2. The mounting portion MM2 may be defined by the third side S33, the fourth side S44, the first imaginary side VS11, and the second imaginary side VS22 of the second driving circuit board CB2. For example, the mounting portion MM2 may refer to an area of the second driving circuit board CB2 surrounded by the third side S33, the fourth side S44, the first imaginary side VS11, and the second imaginary side VS22.

Each of the second pads PD2 of the display panel 110 may extend along a direction parallel to the second side S2 of the second driving circuit board CB2. For example, each of the second pads PD2 may extend along the second direction DR2. In other words, the second pads PD2 may extend in the same direction as the second panel terminals P2 of the second driving circuit board CB2 described above.

The third driving circuit board CB3 has substantially the same structure as the second driving circuit board CB2 described above. Hence, the description of the second driving circuit board CB2 may be applied to the third driving circuit board CB3 of FIG. 4 described above, and any redundant description will be omitted.

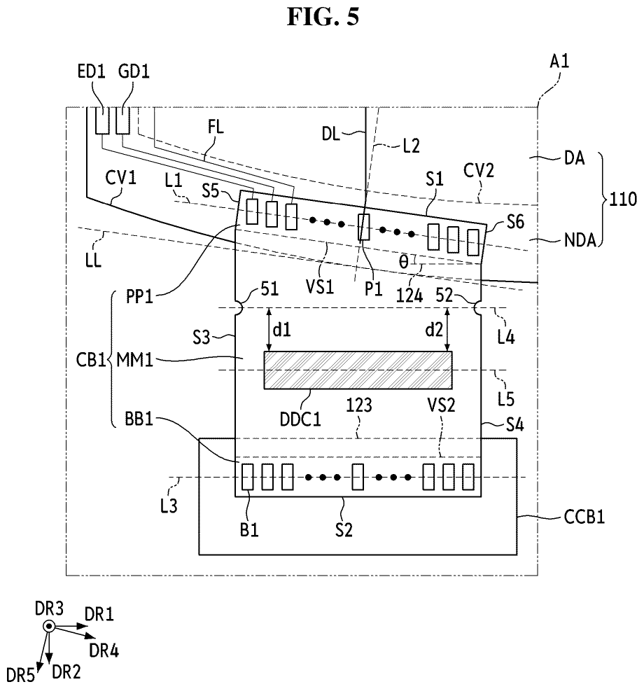

FIG. 5 illustrates another embodiment of the first driving circuit board CB1.

The first driving circuit board CB1 of FIG. 5 is different from the first driving circuit board CB1 of FIG. 3 described above primarily in the extension direction of the first panel terminal P1. Hence, description of FIG. 5 will focus on this difference.

As illustrated in FIG. 5, the plurality of first panel terminals P1 of the panel connection portion PP1 may overlap the plurality of first pads PD1 of the display panel 110, respectively. The first panel terminals P1 may be disposed along the fourth direction DR4.

The first panel terminal P1 may extend along a direction parallel to the third side S3. For example, each of the first panel terminals P1 may extend along the second direction DR2. In this case, each of the first pads PD1 of the display panel 110 may also extend along the second direction DR2.

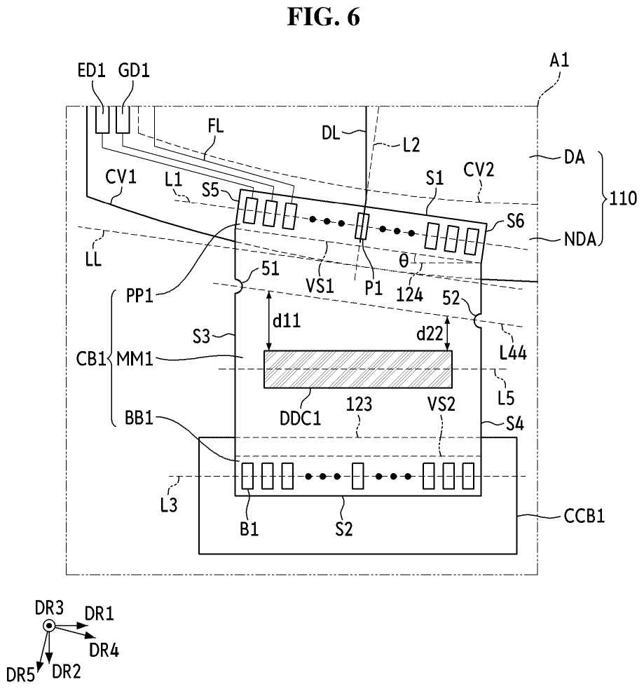

FIG. 6 illustrates still another embodiment of the first driving circuit board CB1.

The first driving circuit board CB1 of FIG. 6 is different from the first driving circuit board CB1 of FIG. 3 described above in terms of the arrangement positions of the first groove 51 and the second groove 52. Hence, FIG. 6 will be described focusing on this difference.

As illustrated in FIG. 6, the first groove 51 and the second groove 52 may face each other in the extension direction of an imaginary fourth line L44. For example, the first groove 51 and the second groove 52 may be disposed on the third side S3 and the fourth side S4, respectively, to face each other in the fourth direction DR4. Accordingly, an imaginary fourth line L44 that passes through the center of the first groove 51 and the center of the second groove 52 may be parallel to the tangent line LL. In other words, the imaginary fourth line L44 may be parallel to the first side S1 of the first driving circuit board CB1.

Additionally, the imaginary fourth line L44 described above may be positioned at different distances from the first end and the second end of the first data driving circuit DDC1. For example, a distance d11 between the fourth line L44 and the first end of the first data driving circuit DDC1 may be greater than a distance d22 between the fourth line L44 and the second end of the first data driving circuit DDC1. According to one embodiment, the distance between the fourth line L44 and the first data driving circuit DDC1 may gradually decrease going (e.g., the first direction DR1) from the first end of the first data driving circuit DDC1 to the second end of the first data driving circuit DDC1.

According to one embodiment, the distance (hereinafter, first distance) between the first end of the first data driving circuit DDC1 described above and the first panel terminal P1 disposed to correspond to the first end of the first data driving circuit DDC1 may be different from the distance (hereinafter, second distance) between the second end of the first data driving circuit DDC1 and the first panel terminal P1 disposed to correspond to the second end of the first data driving circuit DDC1. For example, the first distance may be greater than the second distance. According to one embodiment, in the first driving circuit board CB1, the distance between the first panel terminals P1 and the first data driving circuit DDC1 may gradually decrease going (e.g., the first direction DR1) from the first end of the first data driving circuit DDC1 to the second end of the first data driving circuit DDC1.

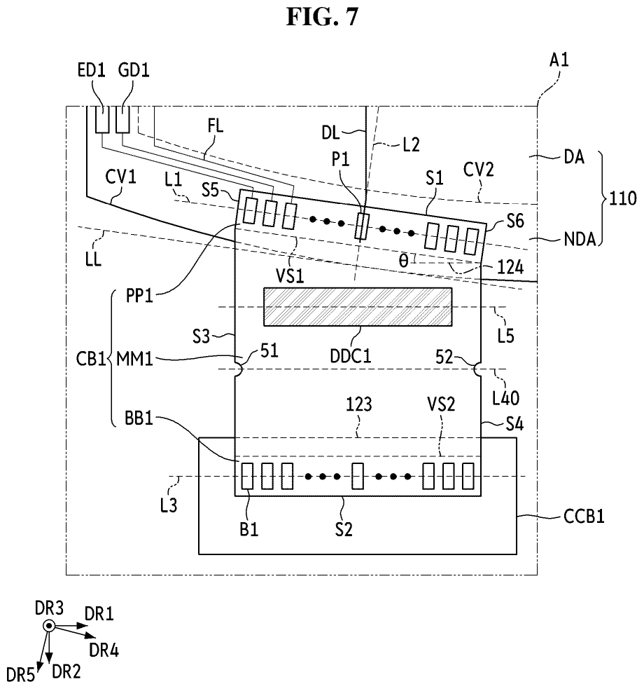

FIG. 7 illustrates still another embodiment of the first driving circuit board CB1.

The first driving circuit board CB1 of FIG. 7 is different from the first driving circuit board CB1 of FIG. 3 described above in terms of the arrangement positions of the first groove 51 and the second groove 52. Hence, FIG. 7 will be described focusing on this difference and redundant details will be omitted.

As illustrated in FIG. 7, the first groove 51 and the second groove 52 may be disposed on the third side S3 and the fourth side S4, respectively, to face each other in the first direction DR1. Accordingly, the imaginary fourth line L40 that passes through the center of the first groove 51 and the center of the second groove 52 may be parallel to the second side S2 of the first driving circuit board CB1.

Additionally, the first groove 51 and the second groove 52 may be disposed between the first data driving circuit DDC1 and the board connection portion BB1. Accordingly, the imaginary fourth line L40 may be disposed between the first data driving circuit DDC1 and the board connection portion BB1.

The first data driving circuit DDC1 of the mounting portion MM1 may be disposed between the imaginary fourth line L40 and the tangent line LL. In other words, the first data driving circuit DDC1 may be disposed on the mounting portion MM1 between the imaginary fourth line L40 and the tangent line LL.

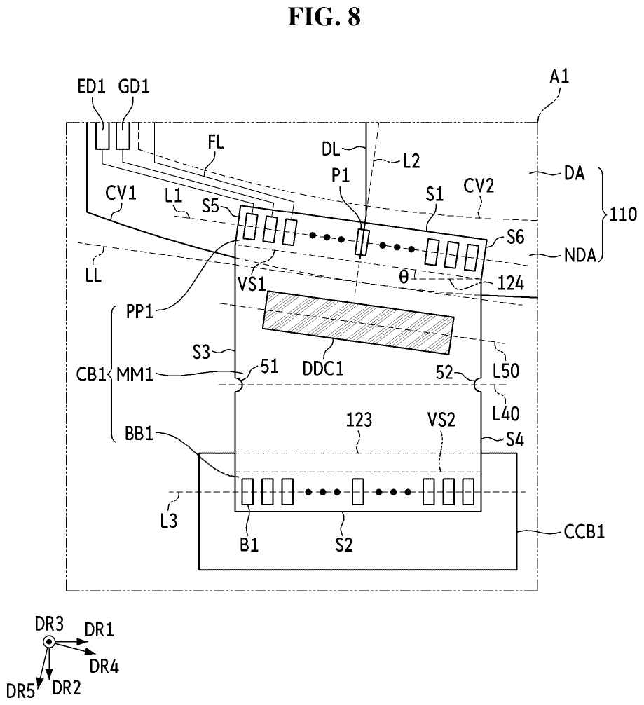

FIG. 8 illustrates still another embodiment of the first driving circuit board CB1.

The first driving circuit board CB1 of FIG. 8 is different from the first driving circuit board CB1 of FIG. 7 described above in terms of the arrangement of the first data driving circuit DDC1. Hence, FIG. 8 will be described focusing on this difference and any redundant description will be mainly described.

As illustrated in FIG. 8, the first data driving circuit DDC1 may have a side that is parallel to a side of the panel connection portion PP1. For example, the first data driving circuit DDC1 may extend along the first side S1 of the panel connection portion PP1. In other words, the first data driving circuit DDC1 may extend along the direction parallel to the tangent line LL or the fourth direction DR4., an imaginary fifth line L50 that is parallel to the direction of the tangent line LL and passes through the center of the first data driving circuit DDC1 may extend along the fourth direction DR4. Accordingly, the sides (e.g., the upper side and the lower side of the first data driving circuit DDC1) facing each other in the fifth direction DR5 of the first data driving circuit DDC1 may be parallel to the first side S1.

The extension direction (e.g., L50) of the first data driving circuit DDC1 may be parallel to the first side S1 and may intersect the second side S2 (or the fourth line L40).

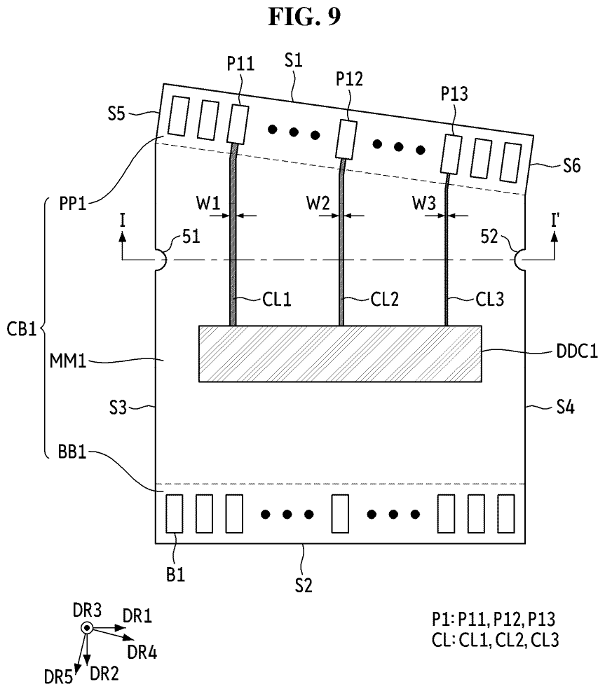

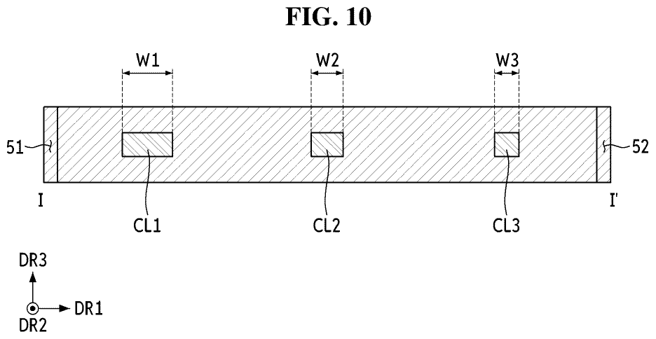

FIG. 9 is a plan view of the first driving circuit board CB1 according to still another embodiment, and FIG. 10 is a cross-sectional view taken along line I-I′ of FIG. 9.

The first driving circuit board CB1 of FIGS. 9 and 10 is different from the first driving circuit board CB1 of FIG. 3 described above in the width of the connection line. Hence, FIG. 9 and FIG. 10 will be described focusing on this difference.

As illustrated in FIGS. 9 and 10, the first driving circuit board CB1 may further include a plurality of connection lines CL that electrically connect the first data driving circuit DDC1 and the plurality of first panel terminals P1 to each other.

The connection lines CL may have different lengths. For example, since the panel connection portion PP1 is inclined with respect to the first data driving circuit DDC1 of the mounting portion MM1, the connection lines CL for connecting the first data driving circuit DDC1 and the first panel terminals P1 of the panel connection portion PP1 to each other may have different lengths. For example, the farther the first panel terminal P1 is positioned from the first data driving circuit DDC1, the longer the connection line to which the first panel terminal P1 may be connected.

According to one embodiment, the longer the connection line, the greater the width of the connection line. For example, a first connection line CL1, which has the longest length among the first connection line CL1, a second connection line CL2, and a third connection line CL3, may have a width W1 that is the largest. The third connection line CL3, which has the shortest length among the first to third connection lines CL1 to CL3 described above, may have a width W3 that is the smallest. Since the length of the second connection line CL2 is greater than the first connection line CL1 and less than the third connection line CL3, the width W2 of the second connection line CL2 may be less than the width W1 of the first connection line CL1 and greater than the width W3 of the third connection line CL3.

The first panel terminals P1 of the panel connection portion PP1 may include, for example, a first-first panel terminal P11, a first-second panel terminal P12, and a first-third panel terminal P13. Here, the first-first panel terminal P11 among the first-first panel terminal P11, the first-second panel terminal P12, and the first-third panel terminal P13 may be disposed farthest from the first data driving circuit DDC1, and the first-third panel terminal P13 among the panel terminals may be disposed closest to the first data driving circuit DDC1. Further, the first-second panel terminal P12 may be disposed closer to the first data driving circuit DDC1 than the first-first panel terminal P11, and may be disposed farther from the first data driving circuit DDC1 than the first-third panel terminal P13.

The first-first panel terminal P11 may be connected to the first connection line CL1 and the first output terminal of the first data driving circuit DDC1, the first-second panel terminal P12 may be connected to the second connection line CL2 and the second output terminal of the first data driving circuit DDC1, and the first-third panel terminal P13 may be connected to the third connection line CL3 and the third output terminal of the first data driving circuit DDC1.

According to one embodiment, since the longer the connection line, the greater the width thereof, the resistance deviation between the connection lines may be minimized. Accordingly, a voltage drop (e.g., IR drop) deviation between the data voltages applied from the first data driving circuit DDC1 to the first data lines may be minimized. Accordingly, the image quality of the display device 100 may be improved.

Although not explicitly illustrated, the second driving circuit board CB2 may also include the plurality of connection lines described above. The plurality of connection lines of the second driving circuit board CB2 may respectively connect the second data driving circuit DDC2 to the plurality of second panel terminals P2. As shown in FIG. 4, the second panel terminal P2 are lined up parallel to the first side S11. And the second data driving circuit DDC2. Hence, the plurality of connection lines of the second driving circuit board CB2 may have the same length and the same width.

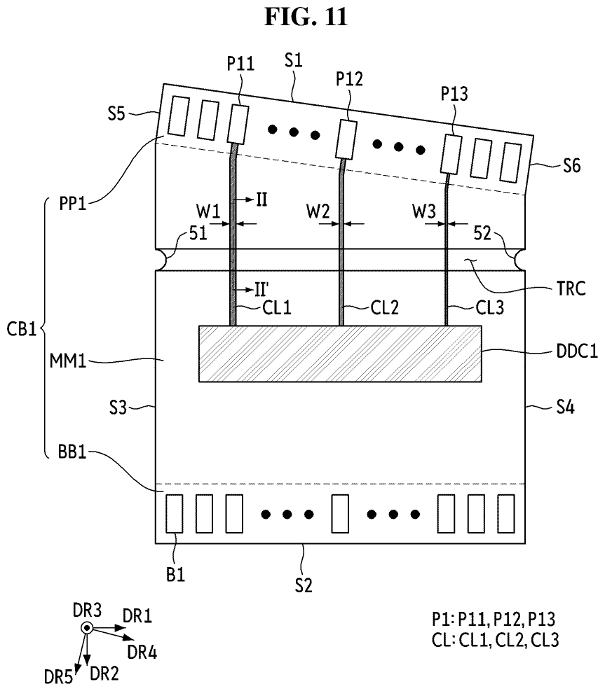

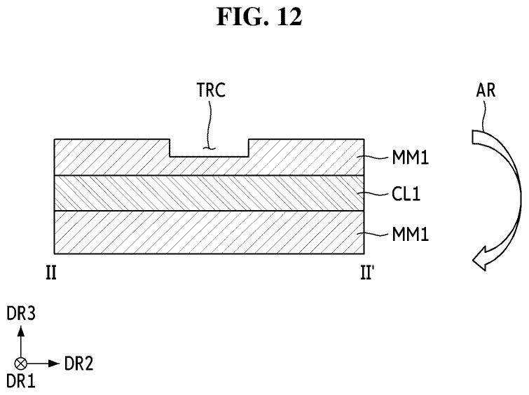

FIG. 11 is a plan view of the first driving circuit board CB1 according to another embodiment, and FIG. 12 is a cross-sectional view taken along line II-II′ of FIG. 11.

The first driving circuit board CB1 of FIGS. 11 and 12 is different from the first driving circuit board CB1 of FIG. 3 described above in that a trench TRC is present. Hence, description of FIG. 11 and FIG. 12 will focus on this difference.

As illustrated in FIGS. 11 and 12, the first driving circuit board CB1 may further include the trench TRC. The trench TRC may extend between the first groove 51 and the second groove 52. The trench TRC may connect the first groove 51 and the second groove 52 to each other.

As illustrated in FIG. 12, the trench TRC may have a recessed shape in the thickness direction of the mounting portion MM1 in the mounting portion MM1 of the first driving circuit board CB1. For example, the trench TRC may have a recessed shape in the reverse third direction (−DR3) that is the opposite direction of the third direction DR3 in the mounting portion MM1. Accordingly, the first driving circuit board CB1 may be thinner in the area where the trench TRC is disposed. In other words, the first driving circuit board CB1 may have a smaller thickness in the area in which the trench TRC is disposed than in the area in which the trench TRC is not disposed. Here, the thickness may be measured as the depth or distance in the third direction DR3.

In plan view as illustrated in FIG. 11, the trench TRC may have a rectangular shape. However, the present disclosure is not limited thereto, and for example, the trench TRC may have a circular shape.

In some embodiments, at least one of the first groove 51 or the second groove 52 may be omitted.

According to one embodiment, the first driving circuit board CB1 may be more easily bent in a clockwise direction along an arrow direction AR due to the trench TRC. Additionally, when the first driving circuit board CB1 rotates in the arrow direction, the stress in the bending area of the first driving circuit board CB1 may be reduced by the trench TRC. Accordingly, when the first driving circuit board CB1 is bent, damage to the connection lines CL in the bending area may be prevented.

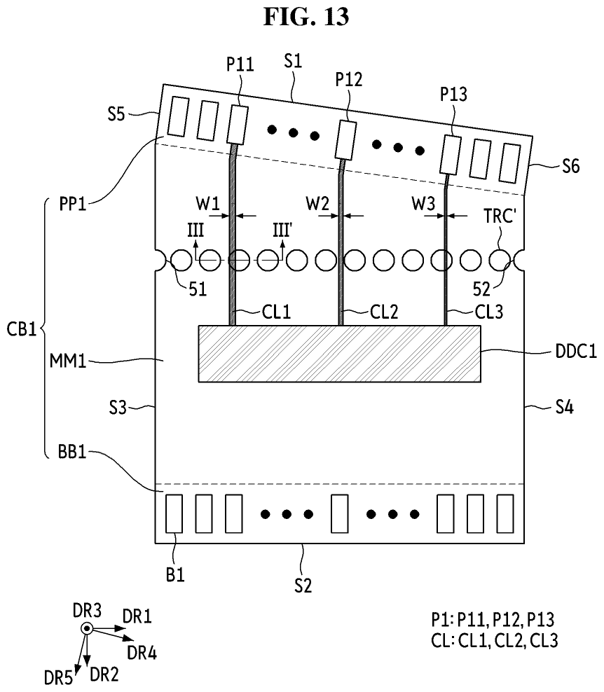

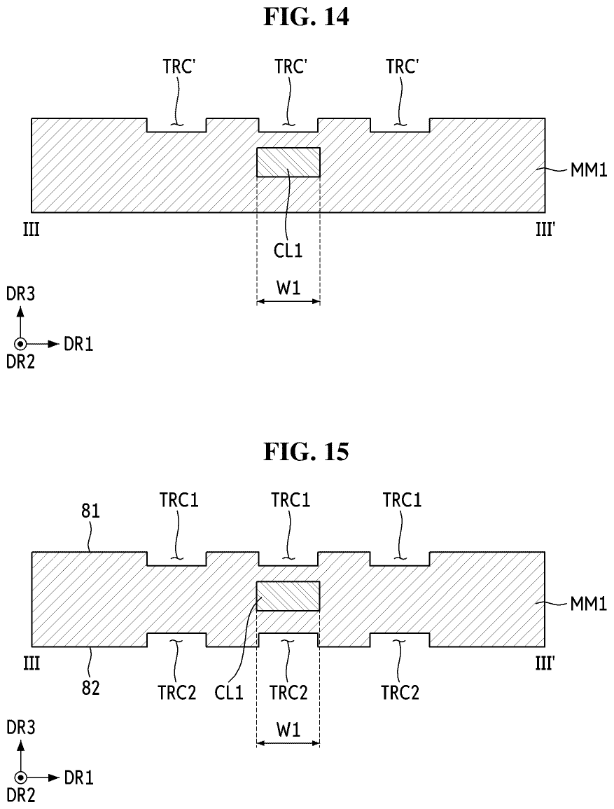

FIG. 13 is a plan view of the first driving circuit board CB1 according to still another embodiment, and FIG. 14 is a cross-sectional view taken along line III-III′ of FIG. 13.

The first driving circuit board CB1 of FIGS. 13 and 14 is different from the first driving circuit board CB1 of FIG. 3 described above in that a plurality of trenches TRC′ are further included, so that the difference will be mainly described as follows.

As illustrated in FIGS. 13 and 14, the first driving circuit board CB1 may further include the plurality of trenches TRC′. The trenches TRC′ may be disposed between the first groove 51 and the second groove 52. The trenches TRC′ may be lined up and spaced apart from each other between the first groove 51 and the second groove 52. The gaps between the adjacent trenches TRC′ may be constant.

As illustrated in FIG. 14, the trench TRC′ may have a recessed shape in the thickness direction of the mounting portion MM1 in the mounting portion MM1 of the first driving circuit board CB1. For example, the trench TRC′ may have a recessed shape in the reverse third direction in the mounting portion MM1. Accordingly, the first driving circuit board CB1 may have a smaller thickness in the area in which the trenches TRC′ are disposed. In other words, the first driving circuit board CB1 may be thinner in the area where the trenches TRC′ are disposed than in the area where the trenches TRC′ are not disposed. Here, the thickness may be the size in the third direction DR3.

In plan view as illustrated in FIG. 13, each trench TRC′ may have a circular shape. However, the present disclosure is not limited thereto, and for example, the trench TRC′ may have a polygonal shape such as a triangle shape or a quadrilateral shape.

In some embodiments, at least one of the first groove 51 or the second groove 52 may be omitted.

FIG. 15 is a cross-sectional view of another embodiment taken along line III-III′ of FIG. 13.

The first driving circuit board CB1 of FIG. 15 is different from the first driving circuit board CB1 of FIG. 14 described above in that a plurality of trenches TRC1 and TRC2 are formed on a top surface 81 and a bottom surface 82, respectively. Hence, description of FIG. 15 will focus on this difference.

As illustrated in FIG. 15, a plurality of first trenches TRC1 and a plurality of second trenches TRC2 may be disposed on the top surface 81 and the bottom surface 82 of the first driving circuit board CB1, respectively.

As illustrated in FIG. 15, the first trench TRC1 may have a recessed shape in the thickness direction of the mounting portion MM1 in the mounting portion MM1 of the first driving circuit board CB1. For example, the first trench TRC1 may have a recessed shape in the reverse third direction in the top surface 81 of the mounting portion MM1. Accordingly, the top surface 81 of the first driving circuit board CB1 may have a smaller thickness in the area in which the first trenches TRC1 are disposed. In other words, the first driving circuit board CB1 may be thinner in the area where the first trenches TRC1 are disposed than in the area where the first trenches TRC1 are not disposed. Thickness may be measured in the third direction DR3.

As illustrated in FIG. 15, the second trench TRC2 may have a recessed shape in the thickness direction of the mounting portion MM1 in the mounting portion MM1 of the first driving circuit board CB1. For example, the second trench TRC2 may have a recessed shape in the third direction DR3 on the bottom surface 82 of the mounting portion MM1. Accordingly, the bottom surface 82 of the first driving circuit board CB1 may be thinner in the area where the second trenches TRC2 are disposed. In other words, the first driving circuit board CB1 may be thinner in the area where the second trenches TRC2 are disposed than in the area where the second trenches TRC2 are not disposed. Thickness may be measured in the third direction DR3.

The first trench TRC1 and the second trench TRC2 may be disposed to face each other in the third direction DR3. For example, the first trench TRC1 and the second trench TRC2 may overlap in the third direction DR3.

According to one embodiment, the first driving circuit board CB1 may be more easily bent by the first trench TRC1 and the second trench TRC1, and stress in the bending area of the first driving circuit board CB1 may be reduced. Accordingly, when the first driving circuit board CB1 is bent, damage to the connection lines CL in the bending area may be prevented.

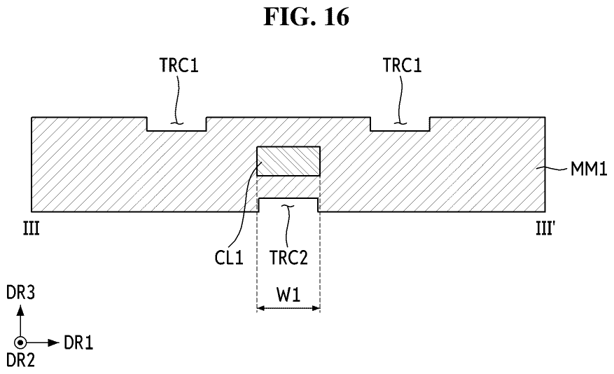

FIG. 16 is a cross-sectional view of still another embodiment taken along line III-III′ of FIG. 13.

The first driving circuit board CB1 of FIG. 16 is different from the first driving circuit board CB1 of FIG. 15 described above in that the trenches TRC1 and TRC2 in the top surface 81 and the bottom surface 82 are disposed so as not to face each other or overlap. Hence, FIG. 16 will be described focusing on this difference.

As illustrated in FIG. 16, a plurality of first trenches TRC1 and a second trench TRC2 may be disposed on the top surface 81 and the bottom surface 82 of the first driving circuit board CB1, respectively. Although one second trench TRC2 is depicted in FIG. 16, there may be more second trenches TRC2.

As illustrated in FIG. 16, the first trench TRC1 may have a recessed shape in the thickness direction of the mounting portion MM1 in the mounting portion MM1 of the first driving circuit board CB1. For example, the first trench TRC1 may have a recessed shape in the reverse third direction in the top surface 81 of the mounting portion MM1. Accordingly, the top surface 81 of the first driving circuit board CB1 may be thinner in the area where the first trenches TRC1 are disposed. In other words, the first driving circuit board CB1 may be thinner in the area where the trenches TRC are disposed than in the area where the trenches TRC are not disposed. Thickness may be measured in the third direction DR3.

As illustrated in FIG. 16, the second trench TRC2 may have a recessed shape in the thickness direction of the mounting portion MM1 in the mounting portion MM1 of the first driving circuit board CB1. For example, the second trench TRC2 may have a recessed shape in the third direction DR3 on the bottom surface 82 of the mounting portion MM1. Accordingly, the bottom surface 82 of the first driving circuit board CB1 maybe thinner in the area in which the second trenches TRC2 are disposed. In other words, the first driving circuit board CB1 may be thinner in the area where the second trenches TRC2 are disposed than in the area in which the second trenches TRC2 are not disposed. The thickness may be the size in the third direction DR3.

The first trench TRC1 and the second trench TRC2 may be disposed so as not to face each other in the third direction DR3. For example, the first trench TRC1 and the second trench TRC2 may not overlap in the third direction DR3. In other words, in plan view, the second trench TRC2 may be disposed between the adjacent first trenches TRC1. Likewise, in plan view, the first trench TRC1 may be disposed between the adjacent second trenches TRC2.

According to one embodiment, the first driving circuit board CB1 may be more easily bent by the first trench TRC1 and the second trench TRC2, and stress in the bending area of the first driving circuit board CB1 may be reduced. Accordingly, when the first driving circuit board CB1 is bent, damage to the connection lines CL in the bending area may be reduced. In addition, since the first trench TRC1 and the second trench TRC2 do not overlap, it is advantageous to form the trenches TRC1 and TRC2 on the top surface 81 and the bottom surface 82 of the first driving circuit board CB1, respectively although the thickness of the first driving circuit board CB1 is not sufficiently large.

According to one embodiment, the first groove 61 and the second groove 62 of at least one of the second driving circuit board CB2 or the third driving circuit board CB3 of FIG. 1 may be disposed between the data driving circuit and the board connection portion BB1, similarly to those of FIG. 7 described above.

According to one embodiment, at least one of the second driving circuit board CB2 or the third driving circuit board CB3 of FIG. 1 may further include the trenches TRC, TRC′, TRC1, and TRC2 as illustrated in FIGS. 11 to 16 described above.

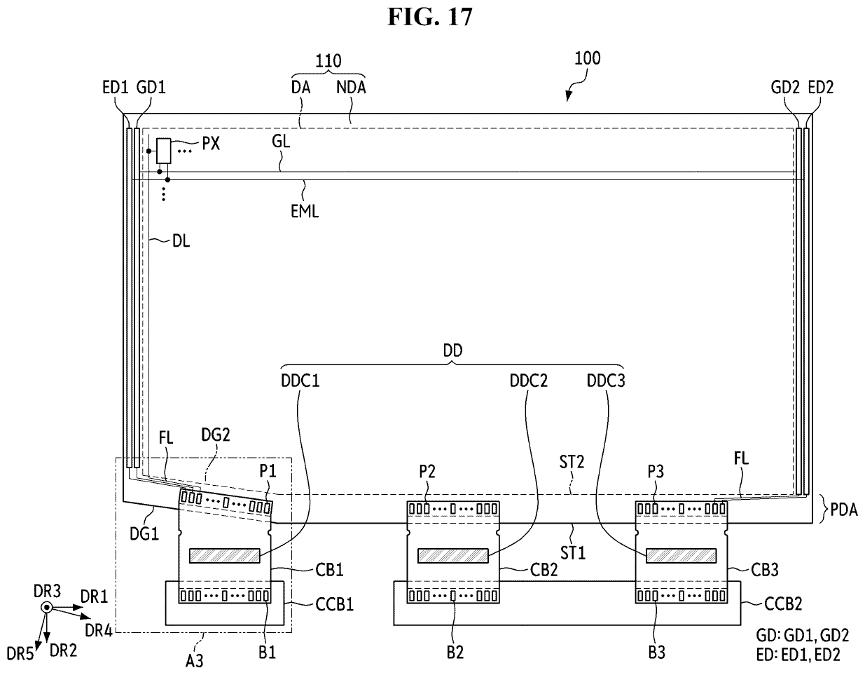

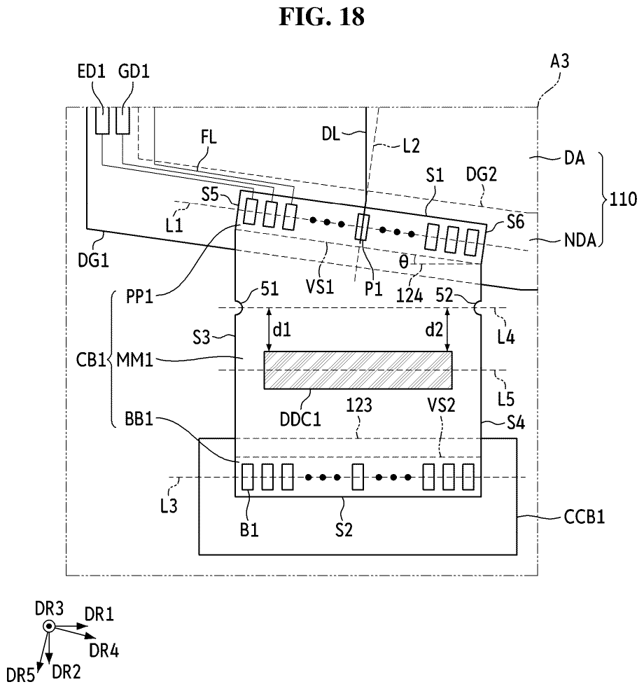

FIG. 17 is a plan view showing a display device according to another embodiment, and FIG. 18 is an enlarged view of area A3 of FIG. 17.

The display device of FIGS. 17 and 18 is different from the display device of FIGS. 1 and 3 described above in that one end of each of the display panel 110 and the display area DA has a diagonal shape. Descriptions of FIG. 17 and FIG. 18 will focus on this difference.

As illustrated in FIGS. 17 and 18, one corner of the display panel 110 may have a diagonal portion DG1 (hereinafter, a first diagonal portion DG1). The first straight portion ST1 of the display panel 110 may be disposed on one side of the first diagonal portion DG1. The first straight portion ST1 may extend, for example, along the first direction DR1.

Additionally, as illustrated in FIGS. 17 and 18, the display area DA may have a shape that is similar to the shape of the display panel 110. For example, one corner of the display area DA may have a diagonal portion DG2 (hereinafter, a second diagonal portion DG2). As a specific example, the second diagonal portion DG2 of the display area DA may be disposed to generally match the outline of the first diagonal portion DG1 of the display panel 110. The second diagonal portion DG2 and the first diagonal portion DG1 may be parallel to each other. The second straight portion ST2 of the display area may be disposed on one side of the second diagonal portion DG2. The second straight portion ST2 may extend, for example, along the first direction DR1. The first straight portion ST1 and the second straight portion ST2 may be disposed parallel to each other.

The first driving circuit board CB1 may be disposed in the non-display area NDA of a diagonal shape between the first diagonal portion DG1 and the second diagonal portion DG2.

According to one embodiment, the first side S1 and the second side S2 of the first driving circuit board CB1 are not parallel. For example, the longest side (e.g., the first side S1) among the sides overlapping the display panel 110 and the longest side (e.g., the second side S2) among the sides overlapping the first control circuit board CCB1 extend in a non-parallel manner. In other words, as the first side S1 is a side that overlaps the display panel 110 above the first data driving circuit DDC1, and the second side S2 is a side that overlaps the first control circuit board CCB1 below the first data driving circuit DDC1, the first side S1 and the second side S2 are nonparallel. Here, the first side S1 may be in contact with the display panel 110, and the second side S2 may be in contact with the first control circuit board CCB1. The angle between the first side S1 and the second side S2 may be greater than 0 degrees. For example, the angle θ between the first imaginary side VS1 parallel to the first side S1 and an imaginary line 124 parallel to the second side S2 may be greater than 0 degrees and less than 90. In an embodiment, the angle (e.g., θ) between the extension direction of the first side S1 and the extension direction of the second side S2 may be 3 degrees.

According to one embodiment, the first side S1 of the first driving circuit board CB1 may be parallel to the first diagonal portion DG1. Additionally, the imaginary first line L1 that passes through the center of the panel connection portion PP1 to intersect the second side S2 perpendicularly may be parallel to the first diagonal portion DG1.

According to one embodiment, the imaginary second line L2 that passes through the center of the panel connection portion PP1 to intersect the first side S1 perpendicularly may intersect the first diagonal portion DG1 perpendicularly. The second line L2 may pass through the center of any one of the first panel terminals P1 connected to the first data lines. For example, when the first data line positioned at the center among the plurality of first data lines connected to the first driving circuit board CB1 is defined as a center data line, and the first panel terminal P1 connected to the center data line is defined as a center panel terminal, the second line L2 described above may pass through the center of the central panel terminal.

According to one embodiment, the first panel terminal P1 may extend along a direction parallel to the fifth side S5. For example, each of the first panel terminals P1 may extend along the fifth direction DR5.

According to one embodiment, the first board terminals B1 may be disposed along the first direction DR1. The first board terminal B1 may extend along a direction parallel to the third side S3. For example, the first board terminals B1 may extend along the second direction DR2.

According to one embodiment, an imaginary third line L3 that passes through the center of the board connection portion BB1 to intersect the third side S3 perpendicularly may not be parallel to the first line L1 (or the first diagonal portion DG1) described above. The angle between the third line L3 and the first line L1 may be equal to the angle (e.g., 0) between the first side S1 and the fourth side S4 described above.

According to one embodiment, the imaginary fourth line L4 that passes through the center of the first groove 51 and the center of the second groove 52 may be parallel to the second side S2 of the first driving circuit board CB1.

According to one embodiment, the imaginary fourth line L4 described above may be positioned at the same distance from one end of the first data driving circuit DDC1 as from the other end of the first data driving circuit DDC1. For example, the distance between the fourth line L4 and one end of the first data driving circuit DDC1 may be equal to the distance between the fourth line L4 and the other end of the first data driving circuit DDC1.

According to one embodiment, since the panel connection portion PP1 of the first driving circuit board CB1 extends along the extension direction of the first diagonal portion DG1 (or the second diagonal portion DG2), the panel connection portion PP1 may be disposed along the first diagonal portion DG1 (or the second diagonal portion DG2) in the non-display area NDA of a diagonal shape between the first diagonal portion DG1 and the second diagonal portion DG2. In addition, accordingly, the panel connection portion PP1 may be disposed in the center of the non-display area NDA of a diagonal shape without encroaching on the display area DA. Accordingly, when the first driving circuit board CB1 is attached to the display panel 110 in the diagonal area, the attachment area of the first driving circuit board CB1 and the display panel 110 may be minimized, and thus the size of the display area DA in the diagonal portion may be prevented from being reduced.

According to one embodiment, the second driving circuit board CB2 and the third driving circuit board CB3 of FIG. 17 may have the same configuration as the second driving circuit board CB2 of FIG. 4 described above.

According to one embodiment, the first driving circuit board CB1 of FIGS. 17 and 18 may have the same configuration as any one of the first driving circuit boards CB1 of FIGS. 5 to 16 described above.

The display device according to the embodiment can be applied to various electronic devices. The electronic device according to one embodiment includes the display device described above and may further include modules or devices having additional functions in addition to the display device.

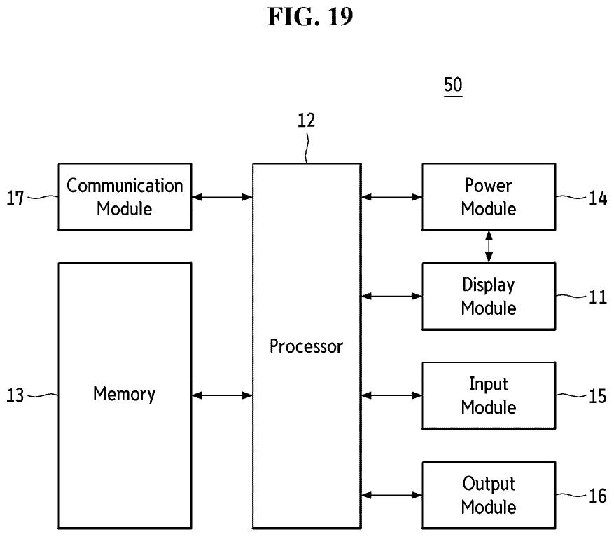

FIG. 19 is a block diagram of an electronic device according to one embodiment. Referring to FIG. 19, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

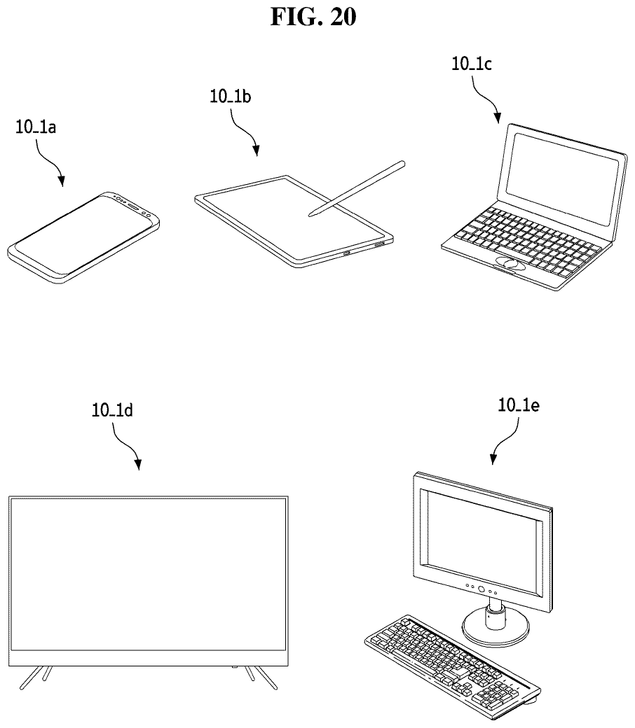

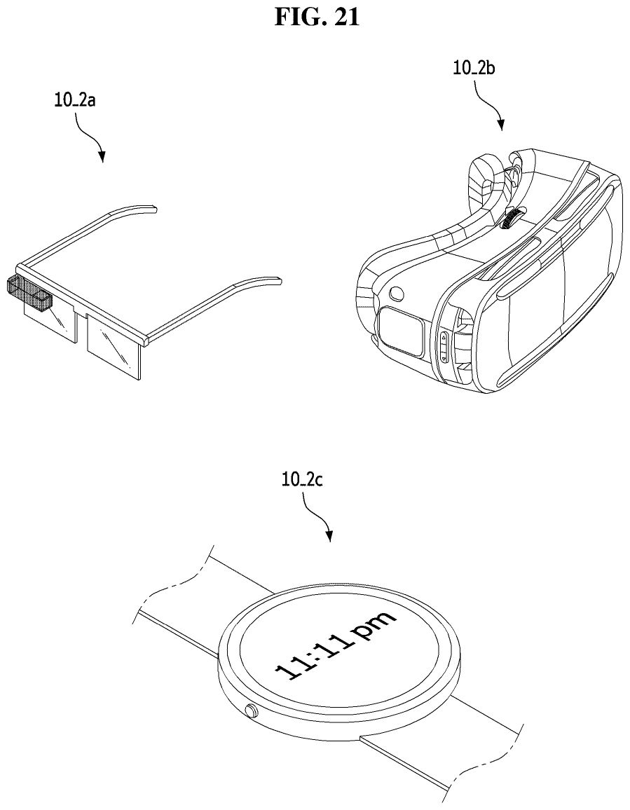

FIGS. 20, 21, and 22 are schematic diagrams of electronic devices according to various embodiments. FIGS. 20 to 22 illustrate examples of various electronic devices to which the display device according to the embodiments is applied.

FIG. 20 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

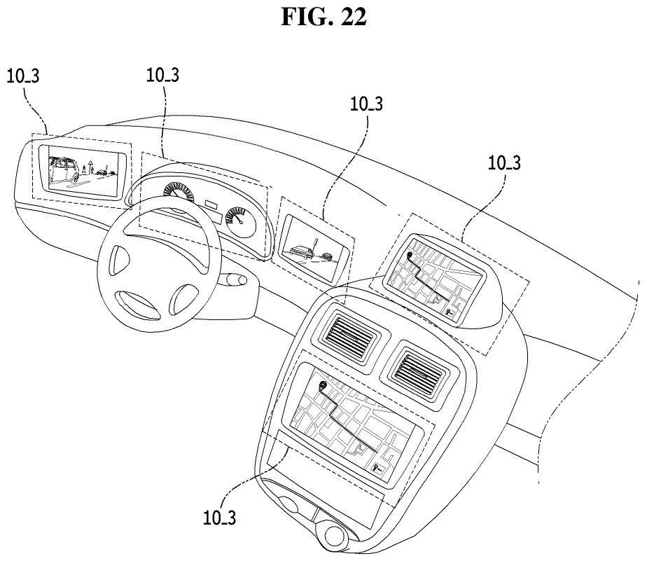

FIG. 21 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 22 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel comprising a display area and a non-display area;
a first circuit board connected to a non-display area of the display panel, the first circuit board being bendable;
a driving circuit disposed on the first circuit board; and
a second circuit board connected to the first circuit board,
wherein the first circuit board comprises a first side overlapping the display panel and a second side overlapping the second circuit board with the driving circuit disposed between the first side and the second side,
the first side is disposed between the display area and a pad of the display panel, and
an extension direction of the first side intersects an extension direction of the second side.

2. The display device of claim 1, wherein an angle between the extension direction of the first side and the extension direction of the second side is greater than 0 degrees and less than 90 degrees.

3. The display device of claim 2, wherein the angle between the extension direction of the first side and the extension direction of the second side is 3 degrees.

4. The display device of claim 1, wherein an entirety of the first side is on the display panel, and
an entirety of the second side is on the second circuit board.

5. The display device of claim 1, wherein the first side is in contact with the display panel, and
the second side is in contact with the second circuit board.

6. The display device of claim 1, wherein the first circuit board further comprises:
a first groove disposed on a third side, the third side extending between a first end of the first side and a first end of the second side; and
a second groove disposed on a fourth side between a second end of the first side and a second end of the second side.

7. The display device of claim 6, wherein the first groove and the second groove are disposed across the first circuit board from each other.

8. The display device of claim 6, wherein an imaginary line passing through a center of the first groove and a center of the second groove intersects the extension direction of the first side.

9. The display device of claim 6, wherein an imaginary line passing through a center of the first groove and a center of the second groove is parallel to the extension direction of the second side.

10. The display device of claim 6, wherein an imaginary line passing through a center of the first groove and a center of the second groove is disposed between the first side and the driving circuit.

11. The display device of claim 6, wherein an imaginary line passing through a center of the first groove and a center of the second groove is disposed between the second side and the driving circuit.

12. The display device of claim 6, wherein an imaginary line passing through a center of the first groove and a center of the second groove is parallel to an extension direction of the driving circuit.

13. The display device of claim 12, wherein the extension direction of the driving circuit is parallel to the extension direction of the second side, and an imaginary line passing through the center of the first groove and the center of the second groove is parallel to the extension direction of the second side.

14. The display device of claim 6, wherein an imaginary line passing through a center of the first groove and a center of the second groove intersects an extension direction of the driving circuit.

15. The display device of claim 14, wherein the extension direction of the driving circuit is parallel to the extension direction of the first side, and
an imaginary line passing through the center of the first groove and the center of the second groove is parallel to the extension direction of the second side.

16. The display device of claim 6, wherein the first groove of the third side is recessed toward the fourth side, and
the second groove of the fourth side is recessed toward the third side.

17. The display device of claim 1, wherein an edge of the display panel overlapping the first circuit board comprises a first curved portion.

18. The display device of claim 17, wherein an edge of the display area comprises a second curved portion disposed to correspond to the first curved portion.

19. The display device of claim 18, wherein the first side is disposed in the non-display area between the first curved portion and the second curved portion.

20. The display device of claim 17, wherein the first side is parallel to a tangent line of the first curved portion.

21. The display device of claim 17, wherein an imaginary straight line that perpendicularly intersects the first side and passes through a center of the first side perpendicularly intersects a tangent line of the first curved portion.

22. The display device of claim 21, wherein the first circuit board further comprises a plurality of panel terminals connected to the display panel, and an imaginary straight line that perpendicularly intersects the first side and passes through the center of the first side passes through a center of any one of the plurality of panel terminals.

23. The display device of claim 22, further comprising a plurality of data lines connected to the driving circuit and disposed in the display area,
wherein the any one panel terminal is connected to any one data line positioned at a center among the plurality of data lines.

24. The display device of claim 22, wherein the any one panel terminal is a panel terminal positioned at a center among the plurality of panel terminals.

25. The display device of claim 1, wherein an edge of the display panel overlapping the first circuit board comprises a first diagonal portion.

26. The display device of claim 25, wherein an edge of the display area comprises a second diagonal portion extending parallel to the first diagonal portion.

27. The display device of claim 26, wherein the first side is disposed in the non-display area between the first diagonal portion and the second diagonal portion.

28. The display device of claim 25, wherein the first side is parallel to the first diagonal portion.

29. The display device of claim 25, wherein an imaginary straight line which perpendicularly intersects the first side and passes through a center of the first side perpendicularly intersects the first diagonal portion.

30. The display device of claim 1, wherein the first circuit board further comprises a panel terminal connected to the display panel, and
the panel terminal extends in a direction perpendicular to the extension direction of the first side.

31. The display device of claim 1, wherein the first circuit board further comprises a panel terminal connected to the display panel, and
the panel terminal extends in a direction perpendicular to the extension direction of the second side.

32. The display device of claim 1, wherein the first circuit board further comprises a plurality of panel terminals connected to the display panel, and an arrangement direction of the plurality of panel terminals is parallel to the extension direction of the first side.

33. The display device of claim 32, further comprising a plurality of pads disposed on the display panel and respectively connected to the plurality of panel terminals, wherein an arrangement direction of the plurality of pads is parallel to the extension direction of the first side.

34. The display device of claim 32, wherein the first circuit board comprises a plurality of connection lines connected to the plurality of panel terminals and the driving circuit,
an extension direction of the driving circuit is parallel to the extension direction of the second side,
lengths of the plurality of connection lines increases along the extension direction of the driving circuit, and
a greater length correlates with a greater width for the plurality of connection lines.

35. The display device of claim 1, wherein the first circuit board further comprises a plurality of board terminals connected to the second circuit board, and an arrangement direction of the plurality of board terminals is parallel to the extension direction of the second side.

36. The display device of claim 6, wherein the first circuit board further comprises a trench disposed between the first groove and the second groove.

37. The display device of claim 36, wherein the trench extends between the first groove and the second groove.

38. The display device of claim 6, wherein the first circuit board further comprises a plurality of trenches disposed between the first groove and the second groove.

39. The display device of claim 38, wherein the plurality of trenches are disposed to be spaced apart from each other.

40. The display device of claim 6, wherein the first circuit board comprises:
at least one first trench disposed in a top surface of the first circuit board; and
at least one second trench disposed in a bottom surface of the first circuit board.

41. The display device of claim 40, wherein the at least one first trench and the at least one second trench overlap each other.

42. The display device of claim 40, wherein in plan view, the second trench is disposed between adjacent first trenches.

43. The display device of claim 6, wherein an imaginary line passing through a center of each groove of the plurality of first circuit boards is parallel to a straight portion of the display panel.

44. The display device of claim 1, wherein an imaginary line passing through a center of each of the plurality of second circuit boards is parallel to a straight portion of the display panel.

45. An electronic device comprising:
a processor:
a memory;
a display device:
wherein the display device comprising:
a display panel comprising a display area and a non-display area;
a first circuit board connected to a non-display area of the display panel, the first circuit board being bendable;
a driving circuit disposed on the first circuit board; and
a second circuit board connected to the first circuit board,
wherein the first circuit board comprises a first side overlapping the display panel and a second side overlapping the second circuit board with the driving circuit disposed between the first side and the second side,
the first side is disposed between the display area and a pad of the display panel, and
an extension direction of the first side intersects an extension direction of the second side.

46. The electronic device of claim 45, wherein an angle between the extension direction of the first side and the extension direction of the second side is greater than 0 degrees and less than 90 degrees.

47. The electronic device of claim 46, wherein the angle between the extension direction of the first side and the extension direction of the second side is 3 degrees.

48. The electronic device of claim 45, wherein an entirety of the first side is on the display panel, and
an entirety of the second side is on the second circuit board.
